(19) United States
(12) Patent Application Publication
(10) Pub. No.: US 2026/0357429 A1
(43) Pub. Date: Nov. 12, 2026

(54) SHOWERHEAD WITH THREE PLENUMS

(71) Applicant: LAM RESEARCH CORPORATION, Fremont, CA (US)

(72) Inventors: Aaron Blake MILLER, West Linn, OR (US); Michael Philip ROBERTS, Tigard, OR (US); Sushanth SHETTY, Udupi (IN)

(21) Appl. No.: 19/121,571

(22) PCT Filed: Oct. 19, 2023
(86) PCT No.: PCT/US2023/035479

§ 371 Date: Apr. 16, 2025

Related U.S. Application Data
(60) Provisional application No. 63/418,671, filed on Oct. 24, 2022.

(51) Int. Cl. C23C 16/455; C23C 16/52

(52) U.S. Cl. CPC C23C 16/45565; C23C 16/45536; C23C 16/45544; C23C 16/45572; C23C 16/45574; C23C 16/52

(57) ABSTRACT

A substrate processing system includes a processing chamber, a plasma source to generate and supply plasma to the processing chamber, and a showerhead disposed between the processing chamber and the plasma source to supply gases to the processing chamber and the plasma source and to supply the plasma to the processing chamber. The showerhead includes a body, a first set of holes, and a second set of holes. The body has first, second, and side surfaces that define first and second plenums. The first set of holes extend from the first plenum to the first surface and are in fluid communication with the processing chamber. The second set of holes extend from the second plenum to the second surface and are in fluid communication with the plasma source.

### CROSS-REFERENCE TO RELATED APPLICATIONS

This application claims the benefit of U.S. Provisional Application No. 63/418,671, filed on Oct. 24, 2022. The entire disclosure of the application referenced above is incorporated herein by reference.

### FIELD

The present disclosure relates generally to substrate processing systems and more particularly to a showerhead with three plenums.

### BACKGROUND

The background description provided here is for the purpose of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD processes use at least two chemicals called precursors (reactants) that react with the surface of the material one precursor at a time in a sequential, self-limiting manner. For example, a typical ALD process includes a series of dose and purge steps that are performed sequentially and repeatedly. Through repeated exposure to separate precursors, a thin film is gradually deposited on the surface of the material.

A plasma enhanced ALD (PEALD) process uses plasma following the dose steps. In some substrate processing systems, the plasma may be generated in-situ in a processing chamber. Alternatively, the plasma may be generated externally or remotely from the processing chamber and supplied to the processing chamber.

### SUMMARY

A substrate processing system comprises a processing chamber, a plasma source to generate and supply plasma to the processing chamber, and a showerhead disposed between the processing chamber and the plasma source to supply gases to the processing chamber and the plasma source and to supply the plasma to the processing chamber. The showerhead comprises a body, a first set of holes, and a second set of holes. The body has first, second, and side surfaces that define first and second plenums. The first set of holes extend from the first plenum to the first surface and are in fluid communication with the processing chamber. The second set of holes extend from the second plenum to the second surface and are in fluid communication with the plasma source.

In additional features, the second plenum and the second set of holes are inverted replicas of the first plenum and the first set of holes.

In additional features, the showerhead supplies the gases through the first and second sets of holes uniformly radially and azimuthally across the showerhead.

In additional features, the showerhead supplies the gases through the first and second sets of holes uniformly radially and azimuthally across the showerhead in opposite directions.

In additional features, the showerhead supplies the gases through the first and second sets of holes to the processing chamber and the plasma source, respectively. The showerhead supplies the gases through the first and second sets of holes uniformly radially and azimuthally across the showerhead.

In additional features, the showerhead is cylindrical. The first and second plenums are stacked in an axial direction perpendicular to a diameter of the showerhead. The first and second plenums extend radially across the showerhead.

In additional features, the processing chamber further comprises a pedestal and a substrate arranged on the pedestal. The showerhead is cylindrical. The first and second plenums are stacked in an axial direction perpendicular to a diameter of the showerhead. The first and second plenums extend radially fully across the substrate.

In additional features, the second plenum and the second set of holes are disjoint from the first plenum and the first set of holes.

In additional features, the showerhead is cylindrical. The first and second plenums extend radially across the showerhead. The first and second sets of holes are distributed radially across the showerhead.

In additional features, the showerhead is cylindrical. The first and second sets of holes extend in an axial direction perpendicular to a diameter of the showerhead.

In additional features, the first and second sets of holes have the same diameter.

In additional features, showerhead further comprises a third set of holes that extend between the first and second surfaces. The third set of holes are disjoint from the first and second plenums and the first and second sets of holes.

In additional features, the showerhead is cylindrical. The second set of holes supply one of the gases uniformly radially and azimuthally across the showerhead to the plasma source. The third set of holes supply the one of the gases uniformly radially and azimuthally across the showerhead from the plasma source to the processing chamber.

In additional features, the showerhead is cylindrical. The third set of holes extend in an axial direction perpendicular to a diameter of the showerhead.

In additional features, the showerhead is cylindrical. The third set of holes are distributed radially across the showerhead.

In additional features, the showerhead is cylindrical. The first, second, and third sets of holes are distributed interstitially radially across the showerhead.

In additional features, the processing chamber further comprises a pedestal and a substrate arranged on the pedestal. The showerhead is cylindrical. The third set of holes are distributed radially fully across the substrate.

In additional features, the processing chamber further comprises a pedestal and a substrate arranged on the pedestal. The showerhead is cylindrical. The first and second plenums are stacked in an axial direction perpendicular to a diameter of the showerhead. The first and second plenums extend radially fully across the substrate. The third set of holes are distributed radially fully across the substrate.

In additional features, the showerhead is cylindrical. A diameter of the third set of holes is greater than or equal to diameters of at least one the first and second sets of holes.

In additional features, the showerhead is cylindrical. The first and second sets of holes have a first diameter. The third set of holes have a second diameter that is greater than the first diameter.

In additional features, the third set of holes supply radicals from the plasma to the processing chamber.

In additional features, the showerhead is cylindrical. The showerhead further comprises a cooling channel disposed between the first and second plenums. The cooling channel and the first and plenums extend radially across the showerhead and are disjoint from each other.

In additional features, the plasma source is dome shaped, elliptical, cylindrical, or conical.

In additional features, the substrate processing system further comprises a gas delivery system to supply the gases to the showerhead and a controller. The controller is configured to supply a first gas from the gases to the first plenum during a dose step of an atomic layer deposition (ALD) process. The controller is configured to supply a second gas from the gases to the second plenum to generate the plasma, the third set of holes supplying radicals from the plasma to the processing chamber. The controller is configured to supply a third gas from the gases to the second plenum during a purge step of the ALD process. The third gas flows through the third set of holes uniformly radially and azimuthally across the showerhead into the processing chamber preventing flow of material from the processing chamber to the plasma source.

In still other features, a showerhead comprises a body, a first set of holes, and a second set of holes. The body has first, second, and side surfaces that defines first and second plenums. The first and second surfaces are opposite to each other. The first set of holes extend from the first plenum to the first surface. The second set of holes extend from the second plenum to the second surface.

In additional features, the second plenum and the second set of holes are inverted replicas of the first plenum and the first set of holes.

In additional features, the showerhead is cylindrical. The first and second plenums are stacked in an axial direction perpendicular to a diameter of the showerhead. The first and second plenums extend radially across the showerhead.

In additional features, the second plenum and the second set of holes are disjoint from the first plenum and the first set of holes.

In additional features, the showerhead is cylindrical. The first and second plenums extend radially across the showerhead. The first and second sets of holes are distributed radially across the showerhead.

In additional features, the showerhead is cylindrical. The first and second sets of holes extend in an axial direction perpendicular to a diameter of the showerhead.

In additional features, the first and second sets of holes have the same diameter.

In additional features, the showerhead further comprises a third set of holes that extend between the first and second surfaces. The third set of holes are disjoint from the first and second plenums and the first and second sets of holes.

In additional features, the showerhead is cylindrical. The third set of holes extend in an axial direction perpendicular to a diameter of the showerhead.

In additional features, the showerhead is cylindrical. The third set of holes are distributed radially across the showerhead.

In additional features, the showerhead is cylindrical. The first, second, and third sets of holes are distributed interstitially radially across the showerhead.

In additional features, the showerhead is cylindrical. The third set of holes are greater in diameter than the first and second sets of holes.

In additional features, the showerhead is cylindrical. The first and second sets of holes have a first diameter. The third set of holes have a second diameter that is greater than the first diameter.

In additional features, the showerhead is cylindrical. The showerhead further comprises a cooling channel disposed between the first and second plenums. The cooling channel and the first and plenums extend radially across the showerhead and are disjoint from each other.

In still other features, a substrate processing system comprises a processing chamber, a plasma source to generate and supply plasma to the processing chamber, and a showerhead disposed between the processing chamber and the plasma source to supply gases to the processing chamber and to supply radicals from the plasma to the processing chamber. The showerhead comprises a body, a first plenum, a second plenum, and a third plenum. The body has first, second, and side surfaces defining the first, second, and third plenums. The first surface faces the plasma source, and the second surface faces the processing chamber. The first plenum comprises a first set of holes extending from the first surface to the second surface of the showerhead. The first set of holes is in fluid communication with the plasma source and the processing chamber. The second plenum comprises a second set of holes extending from the second plenum to the second surface. The second set of holes is in fluid communication with the processing chamber. The third plenum is arranged between the second plenum and the second surface. The third plenum comprises a third set of holes extending from the third plenum to the second surface. The third set of holes is in fluid communication with the processing chamber.

In additional features, the third plenum is configured to supply a gas to the processing chamber during a first time period and to exhaust material from the processing chamber during a second time period to prevent flow of the material from processing chamber through the first set of holes into the plasma source.

In additional features, the third plenum further comprises a fourth set of holes extending from the third plenum to the second surface. The fourth set of holes is in fluid communication with the processing chamber. A pair of adjacent holes in the third and fourth sets of holes is arranged on opposite sides of a hole in the second set of holes of the second plenum. The pair of adjacent holes in the third and fourth sets of holes is arranged between a pair of adjacent holes of the first plenum.

In additional features, the third plenum comprises a removable plate configured to attach to an upper portion of the showerhead. The removable plate comprises the third and fourth sets of holes of the third plenum, the second surface of the showerhead, and portions of the first and second sets of holes of the first and second plenums. The upper portion comprises the second plenum and remaining portions of the first and second sets of holes of the first and second plenums.

In additional features, the first plenum is configured to supply the radicals from the plasma source through the first set of holes to the processing chamber. The second plenum is configured to supply a precursor to the processing chamber. The third plenum is configured to prevent flow of the precursor from the processing chamber through the first set of holes into the plasma source by supplying a purge gas through the third set of holes during a first time period and by exhausting the precursor from the processing chamber through the third set of holes during a second time period.

In additional features, the first plenum is configured to supply the radicals from the plasma source through the first set of holes to the processing chamber. The second plenum is configured to supply a precursor to the processing chamber. The third plenum is configured to prevent flow of the precursor from the processing chamber through the first set of holes into the plasma source by supplying a purge gas through the third and fourth sets of holes during a first time period and by exhausting the precursor from the processing chamber through the third set of holes during a second time period.

In additional features, the first, second, and third plenums are disjoint.

In additional features, the showerhead is cylindrical. The first, second, and third plenums extend radially across the showerhead. The first, second, and third sets of holes are distributed radially across the showerhead.

In additional features, the showerhead is cylindrical. The first, second, and third plenums extend radially across the showerhead. The first, second, third, and fourth sets of holes are distributed radially across the showerhead.

In additional features, the showerhead is cylindrical. The first, second, and third sets of holes extend in an axial direction perpendicular to a diameter of the showerhead.

In additional features, the showerhead is cylindrical. The first, second, third, and fourth sets of holes extend in an axial direction perpendicular to a diameter of the showerhead.

In additional features, the showerhead is cylindrical. The first, second, and third sets of holes are distributed interstitially radially across the showerhead.

In additional features, the showerhead is cylindrical. The first, second, third, and fourth sets of holes are distributed interstitially radially across the showerhead.

In additional features, the processing chamber comprises a pedestal and a substrate arranged on the pedestal. The showerhead is cylindrical. The first, second, and third sets of holes are distributed radially fully across the substrate.

In additional features, the processing chamber comprises a pedestal and a substrate arranged on the pedestal. The showerhead is cylindrical. The first, second, third, and fourth sets of holes are distributed radially fully across the substrate.

In additional features, the showerhead is cylindrical. The showerhead further comprises a cooling channel disposed between the first surface of the showerhead and the second plenum. The cooling channel and the first, second, and third plenums extend radially across the showerhead and are disjoint from each other.

In additional features, the third set of holes has a larger diameter than the second set of holes and a smaller diameter than the first set of holes.

In additional features, the third and fourth sets of holes have a larger diameter than the second set of holes and a smaller diameter than the first set of holes.

In still other features, a showerhead for a substrate processing system comprises a body, a first set of holes, a second set of holes, and a third set of holes. The body has first, second, and side surfaces defining first, second, and third plenums. The third plenum is arranged between the second plenum and the second surface of the showerhead. The third plenum is configurable as a supply plenum and an exhaust plenum. The first set of holes of the first plenum extend from the first surface to the second surface. The second set of holes extend from the second plenum to the second surface. The third set of holes extend from the third plenum to the second surface, the third set of holes.

In additional features, the third plenum is configured to supply a gas to a processing chamber during a first time period and to exhaust material from the processing chamber during a second time period to prevent flow of the material from processing chamber into the first set of holes.

In additional features, the showerhead further comprises a fourth set of holes extending from the third plenum to the second surface. A pair of adjacent holes in the third and fourth sets of holes are arranged on opposite sides of a hole in the second set of holes of the second plenum. The pair of adjacent holes in the third and fourth sets of holes are arranged between a pair of adjacent holes of the first plenum.

In additional features, the showerhead further comprises a removable plate configured to attach to an upper portion of the showerhead. The removable plate comprises the third and fourth sets of holes of the third plenum, the second surface of the showerhead, and portions of the first and second sets of holes of the first and second plenums. The upper portion of the showerhead comprises the second plenum and remaining portions of the first and second sets of holes of the first and second plenums.

In additional features, the first plenum is configured to supply radicals from a plasma source through the first set of holes to a processing chamber. The second plenum is configured to supply a precursor to the processing chamber. The third plenum is configured to prevent flow of the precursor from the processing chamber through the first set of holes into the plasma source by supplying a purge gas through the third set of holes during a first time period and by exhausting the precursor from the processing chamber through the third set of holes during a second time period.

In additional features, the first plenum is configured to supply radicals from a plasma source through the first set of holes to a processing chamber. The second plenum is configured to supply a precursor to the processing chamber. The third plenum is configured to prevent flow of the precursor from the processing chamber through the first set of holes into the plasma source by supplying a purge gas through the third and fourth sets of holes during a first time period and by exhausting the precursor from the processing chamber through the third set of holes during a second time period.

In additional features, the first, second, and third plenums are disjoint.

In additional features, the showerhead is cylindrical. The first, second, and third plenums extend radially across the showerhead. The first, second, and third sets of holes are distributed radially across the showerhead.

In additional features, the showerhead is cylindrical. The first, second, and third plenums extend radially across the showerhead. The first, second, third, and fourth sets of holes are distributed radially across the showerhead.

In additional features, the showerhead is cylindrical. The first, second, and third sets of holes extend in an axial direction perpendicular to a diameter of the showerhead.

In additional features, the showerhead is cylindrical. The first, second, third, and fourth sets of holes extend in an axial direction perpendicular to a diameter of the showerhead.

In additional features, the showerhead is cylindrical. The first, second, and third sets of holes are distributed interstitially radially across the showerhead.

In additional features, the showerhead is cylindrical. The first, second, third, and fourth sets of holes are distributed interstitially radially across the showerhead.

In additional features, the showerhead is cylindrical. The showerhead further comprises a cooling channel disposed between the first surface of the showerhead and the second plenum. The cooling channel and the first, second, and third plenums extend radially across the showerhead and are disjoint from each other.

In additional features, the third set of holes has a larger diameter than the second set of holes and a smaller diameter than the first set of holes.

In additional features, the third and fourth sets of holes have a larger diameter than the second set of holes and a smaller diameter than the first set of holes.

In still other features, a substrate processing system comprises a processing chamber, a plasma source to generate and supply plasma to the processing chamber, and a showerhead disposed between the processing chamber and the plasma source to supply gases to the processing chamber and to supply radicals from the plasma to the processing chamber. The showerhead comprises a body, a first plenum, a second plenum, and a third plenum. The body has first, second, and side surfaces defining the first, second, and third plenums. The first surface faces the plasma source, and the second surface faces the processing chamber. The first plenum comprises a first set of holes extending from the first surface to the second surface of the showerhead. The first set of holes is in fluid communication with the plasma source and the processing chamber. The second plenum comprises a second set of holes extending from the second plenum to the second surface. The second set of holes is in fluid communication with the processing chamber. The third plenum is joined to the first plenum.

In additional features, the third plenum is configured to supply a gas to the processing chamber through the first plenum to prevent flow of material from the processing chamber through the first set of holes into the plasma source.

In additional features, the first plenum is configured to supply the radicals from the plasma source through the first set of holes to the processing chamber. The second plenum is configured to supply a precursor to the processing chamber. The third plenum is configured to prevent flow of the precursor from the processing chamber through the first set of holes into the plasma source by supplying a purge gas through the first set of holes.

In additional features, the second plenum is disjoint from the first and third plenums.

In additional features, the third plenum is joined to the first plenum by a plurality of coupling members configured to couple the third plenum to the first set of holes.

In additional features, at intersections of the first and third plenums, portions of the first set of holes under the third plenum extend radially outwards and upwards forming funnel shaped structures that are attached to an underside of the third plenum.

In additional features, the coupling members comprise a plurality of passages connecting the third plenum to the first set of holes. The passages control gas flow from the third plenum to the first set of holes.

In additional features, the passages extend from a center portion of the coupling members o a periphery of the coupling members. The passages extend between top and bottom ends of the coupling members.

In additional features, the coupling members are configured to conduct heat from the second surface of the showerhead to the first surface of the showerhead.

In additional features, the third plenum is joined to the first plenum closer to the first surface of the showerhead than the second surface of the showerhead.

In additional features, the third plenum is joined to the first plenum closer to the second surface of the showerhead than the first surface of the showerhead.

In additional features, the showerhead is cylindrical. The showerhead further comprises a cooling channel. The third plenum is disposed between the first surface of the showerhead and the cooling channel. The second plenum is disposed between the cooling channel and the second surface of the showerhead. The cooling channel and the first, second, and third plenums extend radially across the showerhead.

In additional features, the showerhead is cylindrical. The showerhead further comprises a cooling channel disposed between the first surface of the showerhead and the second plenum. The third plenum is disposed between the second plenum and the second surface of the showerhead. The cooling channel and the first, second, and third plenums extend radially across the showerhead.

In additional features, the showerhead is cylindrical. The first, second, and third plenums extend radially across the showerhead. The first and second sets of holes are distributed radially across the showerhead.

In additional features, the showerhead is cylindrical. The first and second sets of holes extend in an axial direction perpendicular to a diameter of the showerhead.

In additional features, the showerhead is cylindrical. The first and second sets of holes are distributed interstitially radially across the showerhead.

In additional features, the processing chamber comprises a pedestal and a substrate arranged on the pedestal. The showerhead is cylindrical. The first and second sets of holes are distributed radially fully across the substrate.

In additional features, the second set of holes have a smaller diameter than the first set of holes.

In additional features, the second plenum is disjoint from the first and third plenums.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a dual plenum showerhead arranged between a processing chamber and a dome shaped plasma source;

FIGS. 2A-2C schematically illustrate a backstream flow of gases from the processing chamber into the plasma source during a purge step performed in the substrate processing system of FIG. 1;

FIG. 3A shows a first example of a three-plenum showerhead according to the present disclosure;

FIG. 3B shows an example of a pattern of various holes in the showerhead of FIG. 3;

FIG. 4 shows an example of a substrate processing system comprising the showerhead of FIG. 3 arranged between a processing chamber and a dome shaped plasma source;

FIG. 5 shows an example of a substrate processing system comprising the showerhead of FIG. 3 arranged between a processing chamber and an elliptical plasma source;

FIG. 6 shows an example of a substrate processing system comprising the showerhead of FIG. 3 arranged between a processing chamber and a cylindrical plasma source;

FIG. 7A shows an example of a method of processing on a substrate using the showerhead of FIG. 3 in the substrate processing systems of FIGS. 4-6;

FIGS. 7B-7D show examples of gas flows through the showerhead during the method of FIG. 7A;

FIG. 8A shows a second example of a three-plenum showerhead according to the present disclosure;

FIG. 8B shows an example of a divert valve used to operate a purge plenum of the showerheads shown in FIGS. 8A-12C;

FIG. 8C shows an example of a method of processing on a substrate using the showerheads of FIGS. 8A, 11, and 12A-12C in the substrate processing system of FIG. 1;

FIGS. 9A-9F show a third example of a three-plenum showerhead according to the present disclosure;

FIG. 10 shows an example of a method of processing on a substrate using the showerhead of FIGS. 9A-9F in the substrate processing system of FIG. 1;

FIG. 11 shows a fourth example of a three-plenum showerhead according to the present disclosure; and

FIGS. 12A-12C show a fifth example of a three-plenum showerhead according to the present disclosure.

In the drawings, reference numbers may be reused to identify similar and/or identical elements.

### DETAILED DESCRIPTION

In some substrate processing systems, a processing chamber comprises a pedestal to support a substrate, a showerhead arranged at the top of the processing chamber above the pedestal, and a plasma source arranged above the showerhead to supply plasma to the processing chamber. The plasma source is generally a dome shaped structure. The showerhead is arranged between the plasma source and the processing chamber. The showerhead separates the plasma source and the processing chamber. Since the plasma source is external to the processing chamber, the plasma supplied to the processing chamber by the plasma source is called a remote plasma.

An atomic layer deposition (ALD) process may be performed to deposit material on the substrate. An ALD cycle comprises a dose step and a purge step. The showerhead is generally a dual plenum showerhead. During the dose step, a precursor is supplied through a first plenum of the showerhead. A process gas is supplied through an injector located at the top of the plasma source. A coil is disposed around the plasma source. Radio frequency (RF) power is supplied to the coil to activate the process gas and generate plasma in the plasma source. A second plenum of the showerhead comprises through holes (called radical holes). The second plenum is disjoint (i.e., not in fluid communication) from the first plenum. The second plenum (i.e., the radical holes) filters ions in the plasma and supplies radicals from the plasma into the processing chamber. The radicals react with the precursor to deposit material on the substrate. Subsequently, during the purge step, the plasma is extinguished, and a purge gas is supplied through the injector into the plasma source and through the second plenum into the processing chamber to purge the plasma source and the processing chamber. The cycle of the dose step followed by the purge step can be repeated to deposit material on the substrate.

The uniformity of deposition of material on the substrate depends on uniform flow of gases through the plasma source and the processing chamber. However, as described below in detail, due to the geometry of the dome and the central injection point of the gas in the plasma source (hereinafter called the source gas), the gas flow in the plasma source is nonuniform. Further, due to the large size of the radical holes, the nonuniform gas flow in the plasma source perpetuates into the processing chamber. Due to the nonuniform gas flow in the processing chamber, during the post-dose purge step, some of the precursor gets trapped near the center of the substrate instead of getting fully evacuated from the processing chamber. The trapped precursor travels upstream through the large radical holes in the showerhead back into the plasma source (called a backstream problem).

The present disclosure provides a third plenum in the showerhead to solve the backstream problem and to prevent the precursor from traveling upstream from the processing chamber back into the plasma source. As described below in detail, instead of using the injector, the third plenum is used to supply gases into the plasma source. The third plenum is identical to the first plenum, which uniformly supplies precursor into the processing chamber, except that the third plenum is inverted and comprises through holes that face upwards and open into the plasma source. The third plenum creates a uniform flow of the source gas in the plasma source along a horizontal plane across the showerhead (i.e., parallel to the diameter of the showerhead). The source gas flows from the plasma source into the processing chamber through the radical holes uniformly across the diameter of the showerhead.

Due to the flow uniformity achieved upstream from the showerhead in the plasma source, the source gas also flows uniformly downstream through the showerhead into the processing chamber. The uniform gas flow in the processing chamber prevents the precursor from travelling upstream through the center portion of the showerhead back into the plasma source. Accordingly, due to the uniform flow of the source gas in the processing chamber, none of the precursor gets trapped near the center of the substrate and travels upstream through the large radical holes in the showerhead back into the plasma source. Instead, all of the precursor gets pushed out of the processing chamber by the uniform flow of the source gas in the processing chamber and gets purged out (fully evacuated) into an exhaust system downstream of the processing chamber by the vacuum pump.

Specifically, since the first plenum in the showerhead uniformly supplies the precursor into the processing chamber, the present disclosure provides a third plenum that is a replica of the first plenum and that is a mirror image (and therefore an inverted replica) of the first plenum. The third plenum has the same geometry (the same distribution and size of through holes) as that of the first plenum. The third plenum is essentially the same as the first plenum except that the third plenum is rotated by 180 degrees with the through holes facing and opening upwards into the plasma source while the through holes of the first plenum face and open downwards into the processing chamber.

The source gas is supplied through the third plenum from the bottom of the plasma source into the plasma source instead being of supplied from the injector located at the top center of the plasma source. Accordingly, the third plenum supplies the source gas uniformly across the diameter of the showerhead into the plasma source just as the first plenum supplies precursor uniformly across the diameter of the showerhead into the processing chamber. As a result, the source gas flows uniformly through the plasma source and then through the radical holes in the showerhead into the processing chamber.

Additionally, the flow uniformity of the source gas in the plasma source and the processing chamber can be further enhanced by reducing the volume and changing the geometry of the dome of the plasma source. For example, the dome can be reduced to an elliptical enclosure. In some applications, the dome can be replaced by a cylindrical enclosure. Reducing the volume of the dome can reduce cycle times of ALD processes, which increases throughput. Further, reducing the volume of the dome can also reduce the amount of chemistry used in the ALD processes. These and other features of the present disclosure are described below in further detail.

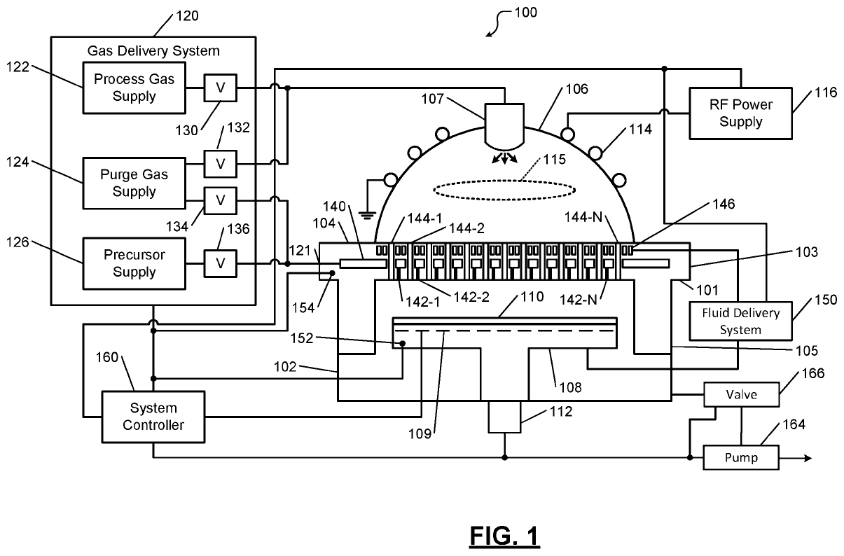

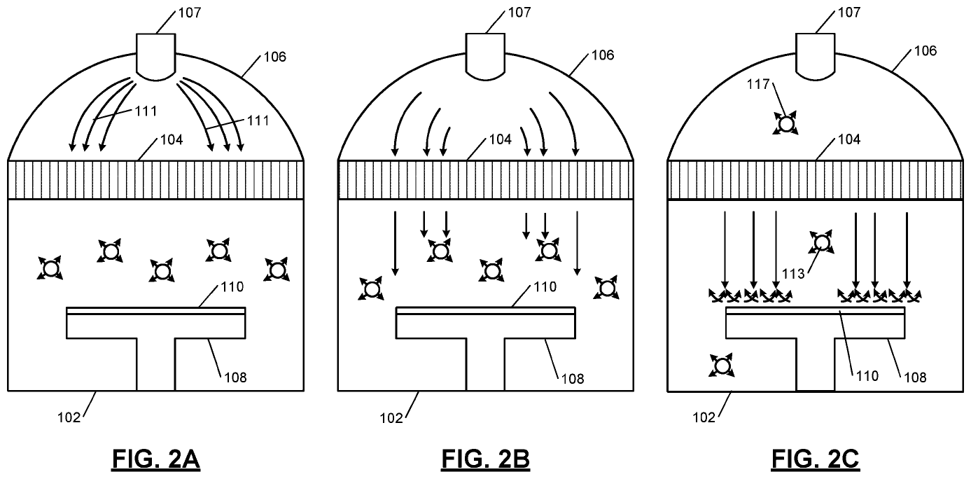

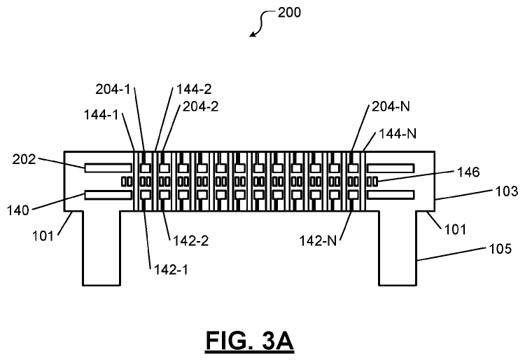

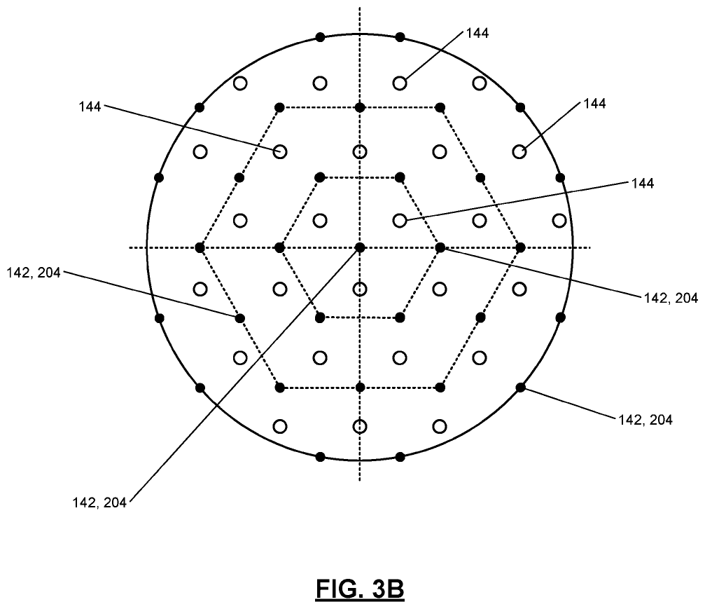

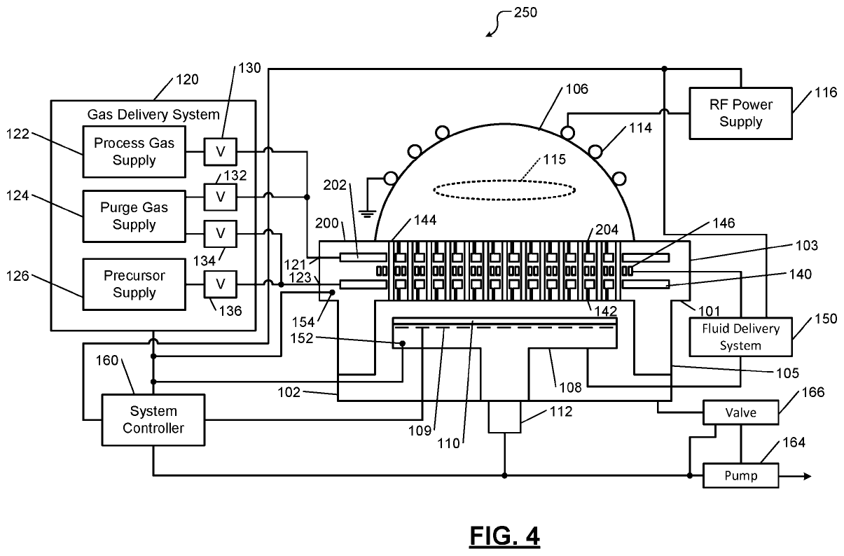

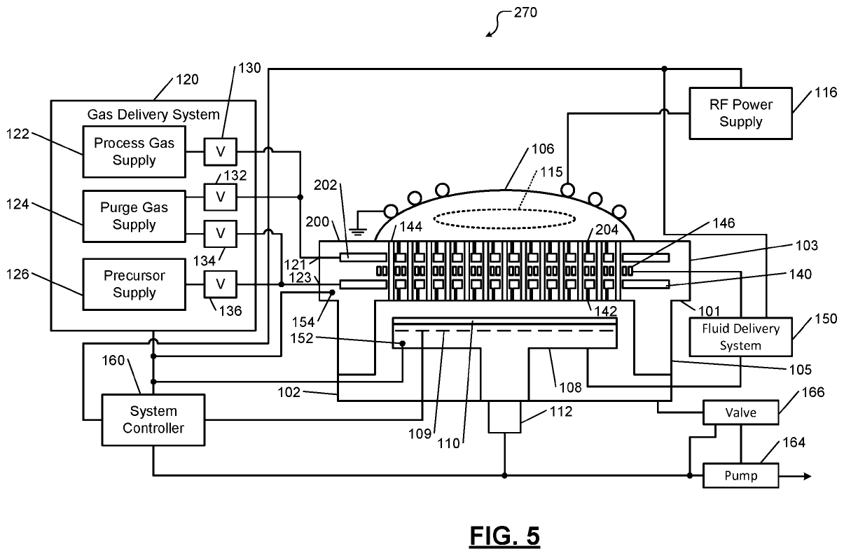

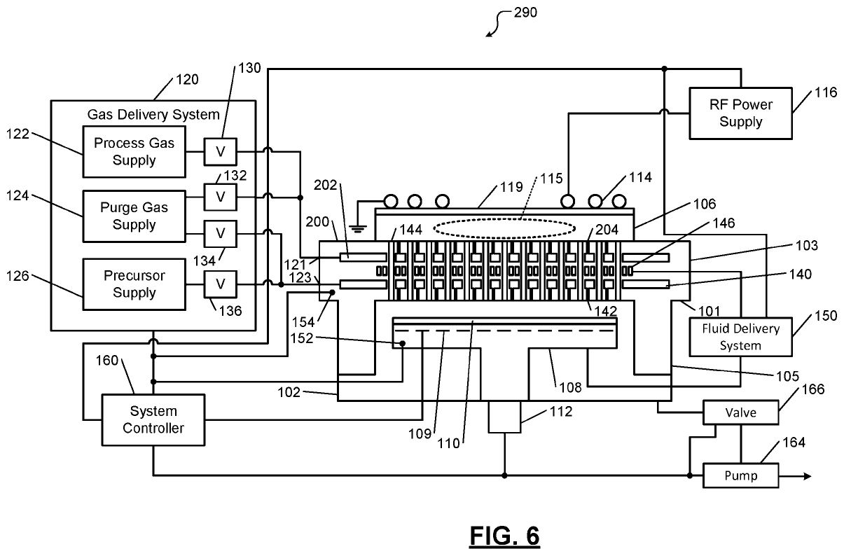

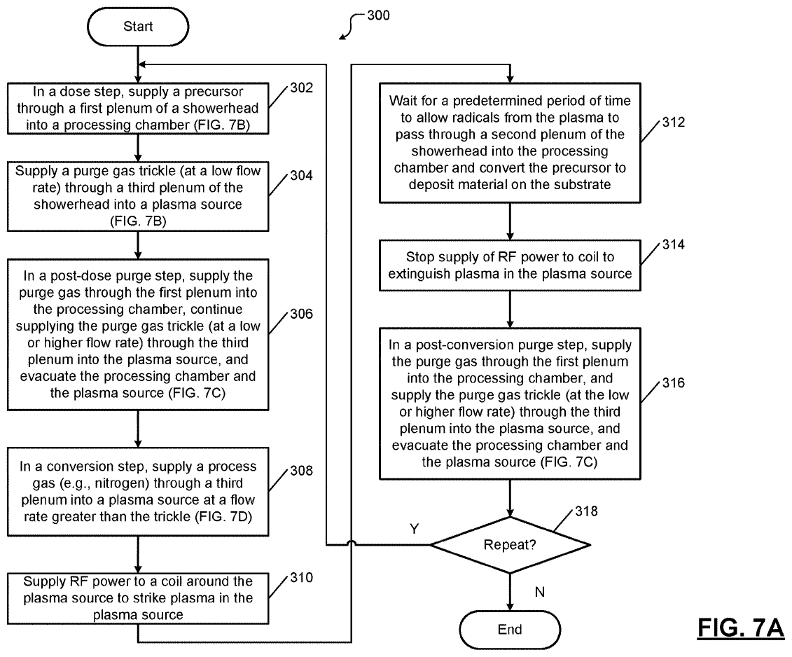

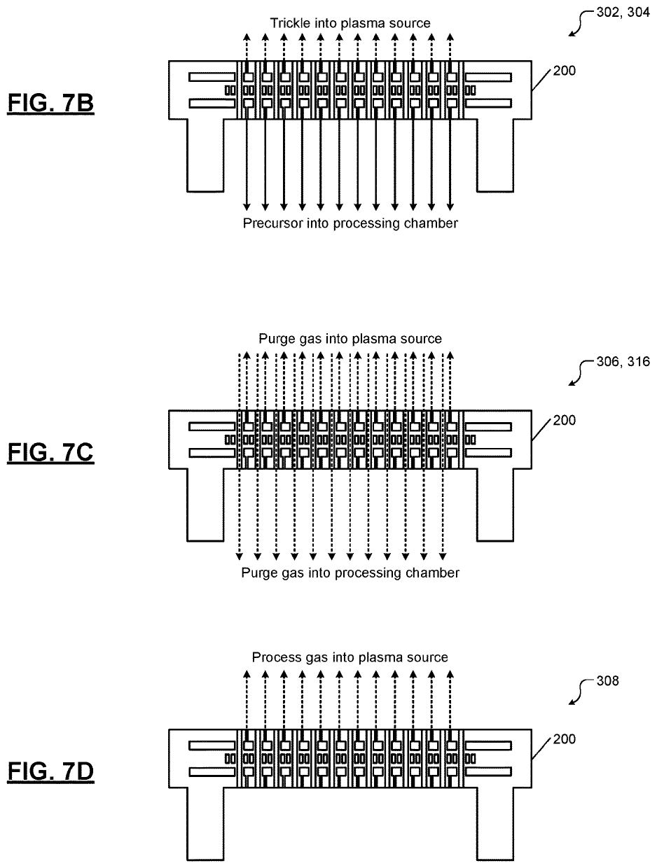

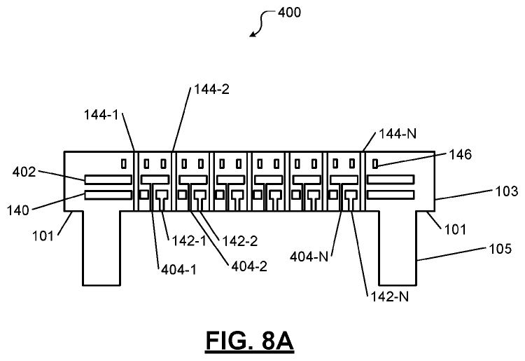

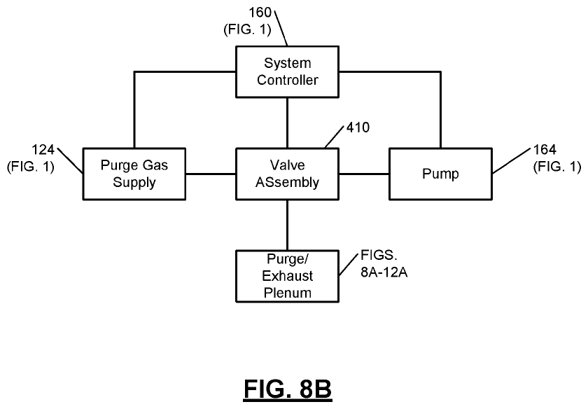

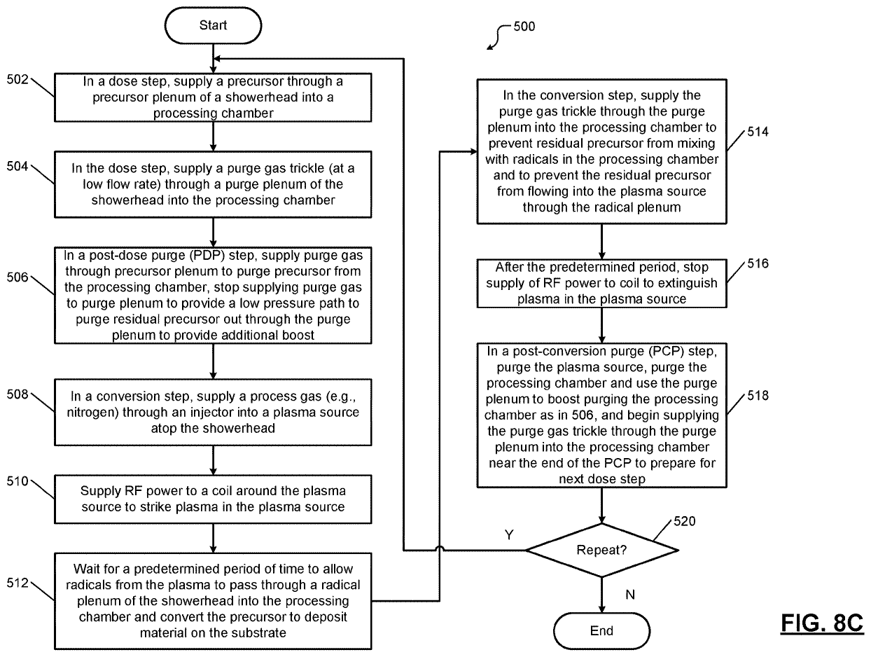

The present disclosure is organized as follows. Initially, to illustrate the problem solved by the present disclosure, an example of a processing chamber with a dual plenum showerhead and dome shaped plasma source is shown and described with reference to FIG. 1. The problem solved by the present disclosure is illustrated and described using FIGS. 2A-2C. A first example of a three-plenum showerhead according to the present disclosure is shown and described with reference to FIGS. 3A and 3B. Examples of substrate processing systems with the three-plenum showerhead are shown and described with reference to FIGS. 4-6. The manner in which the three-plenum showerhead solves the backstream problem is described in detail with reference to FIG. 4. Reducing the volume of the plasma source is described with reference to FIGS. 5 and 6. A method of processing a substrate using the three-plenum showerhead in the substrate processing systems of FIGS. 4-6 and corresponding gas flows through the three-plenum showerhead are shown and described with reference to FIGS. 7A-7D. Additional examples of three-plenum showerheads according to the present disclosure are shown and described with reference to FIGS. 8A-12C.

### Example of System with Dual Plenum Showerhead

FIG. 1 shows an example of a substrate processing system 100 comprising a processing chamber 102, a dual plenum showerhead 104, and a dome shaped plasma source 106. The showerhead 104 comprises a metallic material (e.g., aluminum or an alloy). The plasma source 106 comprises a ceramic (e.g., a dielectric) material. The plasma source 106 has a circular base portion. The plasma source 106 extends upwards from the circular base portion with a dome shaped (e.g., a parabolic or a conical) profile towards a top center portion. The plasma source 106 comprises an injector 107 located at the top center portion of the plasma source 106.

The showerhead 104 is arranged between the plasma source 106 from the processing chamber 102. The showerhead 104 is arranged at the top of the processing chamber 102 and at the bottom of the plasma source 106. The showerhead 104 separates the plasma source 106 from the processing chamber 102. The processing chamber 102 is arranged on a first side (i.e., a substrate-facing side) of the showerhead 104. The plasma source 106 is arranged on a second side of the showerhead 104 that is opposite to the first side of the showerhead 104.

The processing chamber 102 comprises a pedestal 108. A substrate 110 is arranged on the pedestal 108 during processing. An actuator 112 is coupled to a stem portion of the pedestal 108. The actuator 112 can move the pedestal 108 vertically up and down relative to the showerhead 104 to adjust a gap between the substrate 110 and the showerhead 104.

The substrate processing system 100 comprises a gas delivery system 120 that supplies various gases to the processing chamber 102 and the plasma source 106 during substrate processing. For example, the gas delivery system 120 comprises a process gas supply 122, a purge gas supply 124, and a precursor supply 126. The process gas supply 122 can supply one or more process gases (e.g., nitrogen) depending on the process being performed on the substrate 110. The purge gas supply 124 can supply one or more process gases (e.g., one or more inert gases). In some processes, the purge gas may also comprise nitrogen. The precursor supply 126 can supply one or more precursors (reactants) depending on the process being performed on the substrate 110.

Further, while not shown, the gas delivery system 120 may also comprise a cleaning gas supply that can supply one or more cleaning gases to clean the processing chamber 102, the showerhead 104, and the plasma source 106 during preventive maintenance. Furthermore, while not shown, each of the process gas supply 122, the purge gas supply 124, and the precursor supply 126 (and the cleaning gas supply) comprises valves and mass flow controllers to control the supply of respective gases.

The gas delivery system 120 further comprises a plurality of valves (e.g., valves 130, 132, 134, and 136). The process gas supply 122 supplies the one or more process gas to the injector 107 via the valve 130. The purge gas supply 124 can supply the one or more purge gases to the injector 107 via the valve 132. The purge gas supply 124 can supply the one or more purge gases to the showerhead 104 via the valve 134. The precursor supply 126 can supply the one or more precursors to the showerhead 104 via the valve 136.

The showerhead 104 is a dual plenum showerhead. The showerhead 104 is generally cylindrical in shape. The showerhead 104 comprises an upper portion 103 and a lower portion 105. The upper portion 103 is cylindrical. The lower portion 105 is annular. The showerhead 104 is monolithic. That is, the upper portion 103 and the lower portion 105 are integral (i.e., a single piece). The upper portion 103 is also called a body of the showerhead 104. The body (i.e., upper portion 103) of the showerhead 104 comprises upper, lower, and side surfaces that define the plenums in the showerhead 104 as described below in detail.

The plasma source 106 is mounted to the upper portion 103. Specifically, the circular base portion of the plasma source 106 is mounted to the upper portion 103. The lower portion 105 extends vertically downwardly from a lower peripheral region of the upper portion 103. The upper portion 103 extends radially outwardly from an upper region of the lower portion 105 forming a flange 101. Sidewalls of the processing chamber 102 are attached to a lower end of the lower portion 105. The flange 101 extends radially outwardly from the sidewalls of the processing chamber 102.

An outer diameter (OD) of the flange 101 is an OD of the upper portion 103. An OD of the lower portion 105 is the same as an OD of the sidewalls of the processing chamber 102. The OD of the upper portion 103 is greater than the OD of the lower portion 105. An inner diameter (ID) of the lower portion 105 is greater than an OD of the pedestal 108. Accordingly, the pedestal 108 can be moved vertically up and down by the actuator 112 to adjust the gap between the substrate 110 and the showerhead 104.

The showerhead 104 comprises two plenums in the upper portion 103. The two plenums are defined by upper, lower, and side surfaces of the upper portion 103. A first plenum 140 extends radially across the upper portion 103 of the showerhead 104. The first plenum 140 comprises an inlet 121 located on a periphery of the upper portion 103 (e.g., on the flange 101). The first plenum 140 receives the one or more precursors through the inlet 121 from the precursor supply 126 via the valve 136. The first plenum 140 comprises a plurality of holes 142-1, 142-2, . . . , and 142-N (collectively the holes 142, N being a positive integer). The first plenum 140 supplies the one or more precursors via the holes 142 into the processing chamber 102. Accordingly, the holes 142 are also called the precursor holes 142. The inlet 121, the first plenum 140, and the precursor holes 142 are in fluid communication with each other.

The precursor holes 142 extend from the first plenum 140 to a bottom surface (i.e., a substrate-facing surface or a surface facing the processing chamber 102) of the upper portion 103 of the showerhead 104. For convenience, the first plenum 140 comprising the precursor holes 142 is collectively called the precursor plenum 140. The precursor holes 142 are distributed radially across the upper portion 103 of the showerhead 104 from the center of the showerhead 104 up to the ID of the lower portion 105 of the showerhead 104. The diameter of the first plenum 140 is greater than the diameter of the substrate 110.

The upper portion 103 of the showerhead 104 comprises a second plenum comprising a plurality of through holes 144-1, 144-2, . . . , and 144-N (collectively the through holes 144, N being a positive integer). The through holes 144 extend from the top surface of the upper portion 103 to the bottom surface of the upper portion 103 of the showerhead 104. When plasma is formed in the plasma source 106 as described below, ions from the plasma are filtered by the through holes 144, and radicals from the plasma pass via the through holes 144 into the processing chamber 102. Accordingly, the through holes 144 are also called the radical holes 144. The radical holes 144 are distributed radially across the upper portion 103 of the showerhead 104 from the center of the showerhead 104 up to the ID of the lower portion 105 of the showerhead 104.

The radical holes 144 are larger in diameter than the precursor holes 142 (see FIG. 3B). In some implementations, the diameter of the radical holes 144 may also be smaller and therefore equal to the diameter of the precursor holes 142. The radical holes 144 are not in fluid communication with the first plenum 140 and the precursor holes 142. For convenience, the radical holes 144 are collectively called the second plenum 144. The first plenum 140 and the second plenum 144 are disjoint from each other (i.e., not in fluid communication with each other).

A coil 114 is arranged around the plasma source 106. An RF power supply 116 supplies RF power to the coil 114. When a process gas is injected into the plasma source 106 through the injector 107, the RF power supply 116 supplies RF power to the coil 114. The RF power supplied to the coil 114 activates the process gas to generate plasma in the plasma source 106. The second plenum 144 (i.e., the radical holes 144) filters the ions from the plasma and supplies the radicals from the plasma into the processing chamber 102.

The showerhead 104 further comprises a cooling channel 146 disposed in the upper portion 103 of the showerhead 104. The cooling channel 146 is disposed above the first plenum 140 (i.e., the precursor plenum 140). The cooling channel 146 extends radially across the upper portion 103 of the showerhead 104. A fluid delivery system 150 circulates a coolant through the cooling channel 146 via an inlet and an outlet (both not shown) located on the periphery of the upper portion 103 (e.g., on the flange 101). The cooling channel 146, the first plenum 140, and the second plenum 144 are disjoint from each other (i.e., not in fluid communication with each other).

While not shown, the pedestal 108 also comprises cooling channels. The fluid delivery system 150 also circulates the coolant through the cooling channels in the pedestal 108 via an inlet and an outlet (both not shown) provided on the pedestal 108. The pedestal 108 further comprises a heater 109. The heater 109 heats the pedestal 108, which in turn heats the substrate 110. The pedestal 108 comprises a temperature sensor 152 to sense the temperature of the pedestal 108. The showerhead 104 also comprises a temperature sensor 154 to sense the temperature of the showerhead 104. A system controller 160 controls the heater 109 and the supply of the coolant from the fluid delivery system 150 to the pedestal 108 and the showerhead 104 to control the temperatures of the pedestal 108 and the showerhead 104.

The processing chamber 102 comprises a plurality of exhaust ports (not shown) arranged around a lower periphery of the sidewalls of the processing chamber 102. The exhaust ports are coupled to a foreline 162 that is connected to the processing chamber 102. The substrate processing system 100 further comprises a vacuum pump 164 coupled to the processing chamber 102 via the foreline 162 through a valve 166. The vacuum pump 164 maintains pressure (e.g., vacuum) in the processing chamber 102 during substrate processing. The vacuum pump 164 also evacuates gases (e.g., precursors, process gases, purge gases, etc.) and reaction byproducts from the processing chamber 102 during substrate processing and cleaning processes performed during preventive maintenance. The system controller 160 controls all of the elements of the substrate processing system 100 described above.

An example of an ALD cycle comprising a dose step and a purge step that can be performed on the substrate 110 in the substrate processing system 100 is now described. For example, in the dose step, a precursor is supplied through the precursor plenum 142 into the processing chamber 102. A purge gas (e.g., an inert gas) is trickled (i.e., supplied at a low flow rate) through the injector 107 into the plasma source 106 to maintain a positive pressure in the plasma source 106.

A post-dose purge step follows the dose step. In the post-dose purge step, the plasma source 106 and the processing chamber 102 are purged with an inert gas. In the post-dose purge step, the trickle of the inert gas is maintained through the plasma source 106, and the purge gas is supplied through the precursor plenum 140 into the processing chamber 102. In some instances, the flow rate of the purge gas through the plasma source 106 may be increased to more than the trickle.

A conversion step follows the post-dose purge step. In the conversion step, a process gas (e.g., nitrogen) is supplied through the injector 107 into the plasma source 106 at a flow rate greater than the trickle. (Nitrogen can also be supplied as the purge gas used in the purge steps of the ALD cycle.) The RF power supply 116 supplies the RF power to the coil 114, which activates the process gas to strike plasma 115 in the plasma source 106. The second plenum 144 filters the ions from the plasma 115 and supplies the radicals from the plasma 115 into the processing chamber 102. The radicals react with the precursor that is deposited earlier on the substrate 110 during the dose step to deposit the desired material (e.g., silicon nitride) on the substrate 110.

A second purge step follows the conversion step. In the second purge step of the ALD cycle, at the end of the conversion step, the RF power supply 116 stops the supply of the RF power to the coil 114, which extinguishes the plasma 115 in the plasma source 106. The plasma source 106 and the processing chamber 102 are purged as described in the post-dose purge step above. The cycle of these steps is repeated until the material of desired thickness is deposited on the substrate 110. During the purge steps, the vacuum pump 164 evacuates the gases and the reaction byproducts the processing chamber 102.

In some processes, depending on the recipe used for processing the substrate 110, the same or a different precursor may be used in the dose steps in alternate ALD cycles. For example, a first precursor may be used during a first dose step in a first ALD cycle, and a second precursor may be used during a second dose step in a second ALD cycle that follows the first ALD cycle. These ALD cycles are repeated until the material of desired thickness is deposited on the substrate 110.

### Backstream Flow of Precursor

In FIGS. 2A-2C, the backstream flow of the precursor from the processing chamber 102 into the plasma source 106 is now described below in detail. FIGS. 2A-2C schematically show only the processing chamber 102, the showerhead 104, and the plasma source 106 shown in FIG. 1. FIGS. 2A-2C are used to illustrate the backstream flow that occurs in the substrate processing system 100 shown in FIG. 1.

FIG. 2A shows the start of post-dose purge step. When the source gas is injected into the plasma source 106 through the injector 107 at the top center portion of the dome of the plasma source 106, the source gas enters the dome through a small orifice of the injector 107 and expands into a large area of the dome. As a result, the flow of the source gas tends to be more concentrated towards the periphery of the plasma source 106 than near the center of the plasma source 106 as shown by arrows 111. Additionally, while spreading, the source gas also tends to recirculate in the dome, which creates recirculation zones in the dome. Consequently, the source gas spreads throughout the dome non-uniformly.

Meanwhile, the precursor, which was injected into the processing chamber 102 during the dose step preceding the post-dose purge step through the precursor plenum 140, remains in the processing chamber 102 at dose levels while the flow of the source gas develops in the dome of the plasma source 106. At this point in the post-dose purge step, the flow of the source gas from the plasma source 106 through the second plenum 144 of the showerhead 104 into the processing chamber 102 is more concentrated towards the edge of the substrate 110 than the center of the substrate 110 (called edge-heavy flow). This nonuniform flow of the source gas in the plasma source 106 and into the processing chamber 102 is caused by the geometry of the plasma source 106 and the central point of injection of the source gas through the injector 107 located at the top center portion of the dome of the plasma source 106.

FIG. 2B shows the progress of the post-dose purge step. The radical holes 144 are designed with a large diameter to not restrict the flow of radicals from the plasma source 106 upstream of the showerhead 104 into the processing chamber 102 (to ensure that the radicals reach the substrate 110). Due to the large size of the radical holes 144, the flow of the source through the radical holes 144 into the processing chamber 102 downstream from the showerhead 104 is also nonuniform similar to the nonuniform flow of the source gas in the plasma source 106 upstream from the showerhead 104. In other words, due to the geometry of the dome, the central injection point of the source gas, and the large size of the radical holes 144, the nonuniformity of the flow of the source gas in the plasma source 106 translates or replicates into the processing chamber 102.

At this point in the post-dose purge step, the precursor begins to get pushed out of the processing chamber 102 by the source gas being purged out (evacuated) into the exhaust system downstream from the processing chamber 102 by the vacuum pump 164. However, due to the nonuniform and edge-heavy flow of the source gas in the processing chamber 102, the precursor evacuation is also predominant near the edge of the substrate 110 than near the center of the substrate 110.

FIG. 2C shows further progress of the post-dose purge step. The source gas now begins to distribute laterally through the showerhead 104. The edge-heavy flow of the source gas in the processing chamber 102 leaves an opening near the center of the substrate 110 and a curtain around the edge of the substrate 110, which forces the precursor to travel up through the center portion of the showerhead 104 back into the plasma source 106. Accordingly, due to the nonuniform flow of the source gas in the processing chamber 102, instead of getting fully evacuated from the processing chamber 102, some of the precursor gets trapped near the center of the substrate 110 as shown at 113. The trapped precursor travels upstream through the large radical holes 144 back into the plasma source 106 as shown at 117 since the large radical holes 144 do not restrict the flow of the precursor causing the backstream flow of the precursor into the plasma source 106, which is undesirable.

### First Example of a Three Plenum Showerhead

FIGS. 3A and 3B show the three-plenum showerhead 200 comprising a third plenum according to the present disclosure. The showerhead 200 solves the backstream problem described above as follows. Specifically, during the post-dose purge step, the third plenum of the showerhead 200 provides a uniform flow (radially and azimuthally across the showerhead 200) of the source gas both upstream from the showerhead 200 in the plasma source 106 and also downstream from the showerhead 200 in the processing chamber 102. The uniform flow of the source gas upstream and downstream from the showerhead 200 prevents the precursor from flowing upstream from the processing chamber 102 back into the plasma source 106, which solves the backstream problem described above. The three-plenum showerhead 200 is now described below in detail with reference to FIGS. 3A, 3B, and 4. Subsequently, examples of additional substrate processing systems comprising the showerhead 200 are shown and described with reference to FIGS. 5 and 6.

FIG. 4 shows a substrate processing system 250 comprising the showerhead 200. The plasma source 106 in the substrate processing system 250 has the same dome shape as in FIG. 1. FIG. 5 shows a substrate processing system 270 comprising the showerhead 200. The plasma source 106 in the substrate processing system 270 has an elliptical shape. FIG. 6 shows a substrate processing system 290 comprising the showerhead 200. The plasma source 106 in the substrate processing system 290 has a cylindrical shape.

In FIGS. 3A-6, elements of the showerhead 200 that are identified by the same reference numerals as in the showerhead 104 shown in FIG. 1 are not described again for brevity. Further, in FIGS. 4-6, elements of the substrate processing systems 250, 270, and 290 that are identified by the same reference numerals as in the substrate processing system 100 shown in FIG. 1 are not described again for brevity.

In FIGS. 3A, 3B, and 4, the showerhead 200 is also generally cylindrical and comprises the upper and lower portions 103 and 105 and the flange 101 as the showerhead 104. The showerhead 200 differs from the showerhead 104 only in that the showerhead 200 comprises an additional third plenum 202 that is in addition to the first and second plenums 140 and 144. The first and second plenums 140 and 144 are identical to those shown and described with reference to FIG. 1 above and are therefore not described again for brevity. The body (i.e., upper portion 103) of the showerhead 200 comprises the upper, lower, and side surfaces that define the first, second, and plenums 140, 144, and 202 in the showerhead 200 as described below in detail

The third plenum 202 is disposed in the upper portion 103 of the showerhead 200 above the first plenum 140 and above the cooling channel 146. The cooling channel 146 is disposed between the third plenum 202 and the first plenum 140. The third plenum 202 and the first plenum 140 (and the cooling channel 146 therebetween) are thus stacked in an axial direction relative to the substrate 110. Since the third plenum is disposed in the space available above the cooling channel 146 in the upper portion 103 of the showerhead 200, the external geometries (e.g., diameters and heights) of the upper and lower portions 103 and 105 and the flange 101 of the showerhead 200 are unchanged and are identical to those of the showerhead 104.

The first plenum 140, the second plenum 144, and the third plenum 202 extend radially from the center of the showerhead 200 across the upper portion 103 of the showerhead 200. The first plenum 140, the second plenum 144, and the third plenum 202 extend radially through the upper portion 103 of the showerhead 200 fully across the substrate 100. The first plenum 140 and the third plenum 202 are defined by the upper, lower, and side surfaces of the upper portion 103 of the showerhead 200.

The third plenum 202 is an inverted replica of the first plenum 140. Specifically, the third plenum 202 is identical to the first plenum 140 except that the third plenum 202 is an inverted version of the first plenum 140. Accordingly, the third plenum 202 is the same as the first plenum 140 that is rotated by 180 degrees.

As described above with reference to FIG. 1, the first plenum 140 comprises the precursor holes 142 that face and open downwards into the processing chamber 102 towards the substrate 110. Instead, the third plenum comprises a plurality of holes 204-1, 204-2, . . . , and 204-N (collectively the holes 204, N being a positive integer) that face and open upwards into the plasma source 106. The holes 204 extend from the third plenum 202 to the top surface (i.e., the surface facing the plasma source 106) of the upper portion 103 of the showerhead 200. The first plenum 140 and the third plenum 202 supply gases uniformly (radially and azimuthally across the showerhead 200) into the processing chamber 102 and the plasma source 106 (i.e., in opposite directions), respectively, as explained below in detail.

For convenience, the third plenum 202 and the holes 204 are collectively called the third plenum 202. The holes 204 of the third plenum 202 are distributed radially across the upper portion 103 of the showerhead 200 from the center of the showerhead 200 up to the ID of the lower portion 105 of the showerhead 200. Accordingly, a diameter of the third plenum 202 is greater than the diameter of the substrate 110.

The first plenum 140 (i.e., the precursor plenum 140), the second plenum 144 (i.e., the radical holes 144), and the third plenum 202 are disjoint from each other (i.e., not in fluid communication with each other). Further, the first plenum 140, the second plenum 144, the third plenum 202, and the cooling channel 146 are disjoint from each other (i.e., not in fluid communication with each other).

FIG. 3B shows an example of a pattern of the holes 142 of the first plenum 140, the holes 204 of the third plenum 202, and the radical holes 144. FIG. 3B shows only a portion of the pattern. The pattern is identical when the showerhead 200 is viewed from the top (i.e., downwards from the third plenum 202) and when the showerhead 200 is viewed from the bottom (i.e., upwards from the first plenum 140). The holes 142 of the first plenum 140, the holes 204 of the third plenum 202, and the radical holes 144 are vertical (i.e., parallel to an axis perpendicular to the diameter of the showerhead 200). The holes 142 of the first plenum 140, the holes 204 of the third plenum 202, and the radical holes 144 are parallel to each other and are parallel to the axis perpendicular to the diameter of the showerhead 200.

The holes 142 of the first plenum 140 and the holes 204 of the third plenum 202 have the same diameter. The diameter of the holes 142 of the first plenum 140 and of the holes 204 of the third plenum 202 is less (i.e., smaller) than the diameter of the radical holes 144. In some implementations, the diameter of the radical holes 144 may also be smaller, and therefore the diameter of the holes 142 of the first plenum 140 and of the holes 204 of the third plenum 202 is less than or equal to the diameter of the radical holes 144. Further, in some implementations, the holes 142 of the first plenum 140 and the holes 204 of the third plenum 202 have not the same diameter. For example, the diameter of the holes 204 of the third plenum 202 may need to be optimized to deliver a different type of gas than the precursor delivered by the holes 142 of the first plenum 140. Accordingly, in some implementations, the diameter of the radical holes 144 can be greater than or equal to the diameter of the holes 142 of the first plenum 140 and/or the diameter of the holes 204 of the third plenum 202. That is, the diameter of the radical holes 144 can be greater than or equal to the diameter of at least one of the holes 142 of the first plenum 140 and the diameter of the holes 204 of the third plenum 202. The holes 142 of the first plenum 140, the holes 204 of the third plenum 202, and the radical holes 144 are arranged interstitially in a hexagonal pattern as shown in the example shown in FIG. 3B. Additional examples of patterns of these holes are described below after the description of the FIGS. 5 and 6.

In FIG. 4, the showerhead 200 is arranged between the plasma source 106 from the processing chamber 102. The showerhead 200 separates the plasma source 106 from the processing chamber 102. The showerhead 200 is arranged at the top of the processing chamber 102 and at the bottom of the plasma source 106. Accordingly, the plasma source 106 is disposed above the showerhead 200, and the processing chamber 102 is disposed below the showerhead 200. The processing chamber 102 is arranged on the first side (i.e., the substrate-facing side) of the showerhead 200. The plasma source 106 is arranged on a second side of the showerhead 200 that is opposite to the first side of the showerhead 200.

As described below in detail, the showerhead 200 provides multidirectional (e.g., at least bidirectional) gas flows. The precursor flows through the first plenum 140 from the first (bottom) side of the showerhead 200 into the processing chamber 102 in a second (downward) direction. The process and purge gases flow through the third plenum 202 from the second (top) side of the showerhead 200 into the plasma source 106 in a second (upward) direction. Additionally, the process and purge gases also flow through the second plenum 144 from the plasma source 106 to the processing chamber 102 through the showerhead 200 from the second (top) side to the first (bottom) side of the showerhead 200. Further, these gas flows are uniform (radially and azimuthally) across the showerhead 200 in both the first and second directions. Furthermore, these gases flow uniformly in the plasma source 106 and the processing chamber 102.

In FIG. 4, the gas delivery system 120 is identical to the gas delivery system 120 shown in FIG. 1 except that the outputs of the valves 130 and 132 are connected to the third plenum 202 instead of the injector 107. The third plenum 202 eliminates the injector 107, which is not used in the plasma source 106 of the substrate processing system 250. The third plenum 202 comprises an inlet 123 located on the periphery of the upper portion 103 (e.g., on the flange 101) of the showerhead 200. The third plenum 202 receives the one or more process gases through the inlet 123 from the process gas supply 122 via the valve 130. The third plenum 202 receives the one or more purge gases through the inlet 123 from the purge gas supply 124 via the valve 132. The third plenum 202 supplies the one or more process gases and the one or more purge gases via the holes 204 into the plasma source 106. The inlet 123, the third plenum 202, and the holes 204 are in fluid communication with each other.

Using the third plenum 202, in the substrate processing system 250, the process and purge gases are supplied upwards through the holes 204 in the third plenum 202 into the plasma source 106 instead being supplied downwards through the injector 107 into the plasma source 106. Further, the process and purge gases are supplied through the holes 204 in the third plenum 202 uniformly (radially and azimuthally) across the diameter of the showerhead 200 into the plasma source 106 instead being supplied centrally through the injector 107 into the plasma source 106.

Accordingly, during the post-dose purge step, the purge gas flows uniformly (radially and azimuthally across the showerhead 200) into the plasma source 106 from the third plenum 202 and then flows uniformly (radially and azimuthally across the showerhead 200) through the radical holes 144 (i.e., through the second plenum 144) into the processing chamber 102. Since the purge gas flows uniformly into the processing chamber 102, the precursor in the processing chamber 102 gets pushed out evenly and gets fully evacuated from the processing chamber 102 through the exhaust ports of the processing chamber 102 by the vacuum pump. As a result, due to the uniform flow of the purge gas in the processing chamber 102, none of the precursor gets trapped near the center of the substrate 110, and none of the precursor travels upstream through the large radical holes 144 back into the plasma source 106.

Thus, the third plenum 202 solves the backstream problem of the precursor although the plasma source 106 is still dome shaped. The flow uniformity of the purge gas from the third plenum 202 into the plasma source 106 and into the processing chamber can be further enhanced by changing the geometry of the plasma source as described below with reference to FIGS. 5 and 6.

For convenience, the one or more precursors may be collectively called a first gas, the one or more processes gas may be collectively called a second gas, and the one or more purge gases may collectively be called a third gas. Accordingly, the first plenum 140 (i.e., the precursor plenum 140) uniformly (radially and azimuthally across the showerhead 200) supplies the first gas (the precursor) through the precursor holes 142 (also called a first set of holes) into the processing chamber 102 during dose steps. The third plenum 202 uniformly supplies the second and third gases (i.e., the process and purge gases) through the holes 204 (also called a third set of holes) (radially and azimuthally across the showerhead 200) into the plasma source 106. The second plenum 144 uniformly supplies the second and third gases (i.e., the process and purge gases), which are supplied by the third plenum 202 into the plasma source 106 (radially and azimuthally across the showerhead 200), from the plasma source 106 through the radical holes 144 (also called a second set of holes) into the processing chamber 102 during purge steps. The uniform flow of the purge gas from the plasma source 106 into the processing chamber 102 through the second plenum 144 during purge steps (radially and azimuthally across the showerhead 200) fully evacuates the precursor from the processing chamber 102 and prevents backstream flow of the precursor from the processing chamber 102 into the plasma source 106.

### MORE EXAMPLES OF SYSTEMS WITH THREE PLENUM SHOWERHEAD

As shown in FIGS. 5 and 6, due to the third plenum 202, the flow uniformity in the processing chamber 102 can be further enhanced and the volume (i.e., amount) of the chemistry used can be reduced by reducing the volume of the plasma source 106 as described below in detail. Specifically, due to the third plenum 202, the shape of the plasma source 106 can also be simplified as follows.

FIG. 5 shows a substrate processing system 270. The substrate processing system 270 is identical to the substrate processing system 250 shown in FIG. 4 except that the plasma source 106 in the substrate processing system 270 is elliptical instead of being dome shaped as shown in the substrate processing system 250 in FIG. 4. In the substrate processing system 270, the plasma source 106 comprises a circular base portion that is attached to the upper portion 103 of the showerhead 200. The extends upwards from the circular base portion with an elliptical profile towards a top center portion. The plasma source 106 comprises a ceramic (e.g., a dielectric) material.

Due to the elliptical shape, the volume of the plasma source 106 in the substrate processing system 270 is less than the volume of the dome shaped plasma source 106 shown in the substrate processing system 250 in FIG. 4. The reduced volume of the plasma source 106 in the substrate processing system 270 further enhances the flow uniformity in the processing chamber 102 as compared to the flow uniformity in the processing chamber 102 in the substrate processing system 250 shown in FIG. 4. Additionally, in the substrate processing system 270, due to the reduced volume of the plasma source 106, the volume (i.e., amount) of the chemistry used is also further reduced as compared to the volume (i.e., amount) of the chemistry used in the substrate processing systems 100 and 250. Further, while not shown, the plasma source 106 in the substrate processing system 270 can also be conical and have a volume that is less than the volume of the dome shaped plasma source 106 shown in the substrate processing system 250 in FIG. 4.

FIG. 6 shows a substrate processing system 290. The substrate processing system 290 is identical to the substrate processing system 250 shown in FIG. 4 except that the plasma source 106 in the substrate processing system 290 is cylindrical instead of being dome shaped as shown in the substrate processing system 250 in FIG. 4. In the substrate processing system 290, the plasma source 106 comprises a circular base portion that is attached to the upper portion 103 of the showerhead 200. The extends vertically upwards along the axis perpendicular to the substrate 110 from the circular base portion with a cylindrical profile.

A dielectric window 119 is arranged on top of the plasma source 106. The dielectric window 119 has the same diameter as the plasma source 106. The coil 114 is arranged on the dielectric window 119. Due to the cylindrical shape and short height (e.g., 0.1-1.0 inch), the volume of the plasma source 106 in the substrate processing system 290 is less than the volume of the dome shaped plasma source 106 in the substrate processing system 250. The volume of the plasma source 106 in the substrate processing system 290 is also less than volume of the plasma source 106 in the substrate processing system 270, which is already less than the volume of the plasma source 106 in the substrate processing system 100. For example, the volume of the plasma source 106 in the substrate processing system 290 can be 0.3 to 3.0 liters while the volume of the plasma source 106 in the substrate processing system 100 is typically 10-12 liters.

The reduced volume of the plasma source 106 in the substrate processing system 290 further enhances the flow uniformity in the processing chamber 102 as compared to the flow uniformity in the processing chamber 102 in the substrate processing systems 250 and 270. Additionally, in the substrate processing system 290, due to the further reduced volume of the plasma source 106, the volume (i.e., amount) of the chemistry used is also further reduced as compared to the volume (i.e., amount) of the chemistry used in the substrate processing systems 250 and 270.

While not shown, the holes 142 of the first plenum 140, the holes 204 of the third plenum 202, and the radical holes 144 can be arranged in other patterns than the example of the pattern shown in FIG. 3B. Further, in the substrate processing systems 250 and 270, the diameters of the holes 142 of the first plenum 140 and the holes 204 of the third plenum 202 can be varied to further enhance the flow uniformity of the gases in the plasma source 106 and in the processing chamber 102.

For example, in the substrate processing systems 250 and 270, the diameters of the holes 142 of the first plenum 140 and the holes 204 of the third plenum 202 can be gradually decreased as the radial distances of the holes 142 of the first plenum 140 and the holes 204 of the third plenum 202 increase from the centers of the first plenum 140 and the third plenum 202. Regardless of the variations in the diameters, the diameters of the holes 142 of the first plenum 140 and the holes 204 of the third plenum 202 are the same and are less than the diameter of the radical holes 144.

Further, while not shown, in some implementations, in the substrate processing systems 250 and 270, the holes 204 of the third plenum 202 need not be vertical. Instead, the holes 204 of the third plenum 202 may be slanted. For example, the holes 204 in a region from a center of the third plenum 202 to about half or three-fourth of the diameter of the third plenum 202 may be slanted. For example, the holes 204 in this region may be sloped radially outwardly. The slope (angle) at which these holes 204 are slanted may increase gradually as the radial distances of these holes 204 increase from the center of the third plenum 202.

Furthermore, while not shown, in some implementations, in the substrate processing systems 250, 270, and 290, the holes 142 of the first plenum 140, the holes 204 of the third plenum 202, and the radical holes 144 need not be cylindrical (or round). Instead, these holes can be of any other polygonal shapes (e.g., hexagonal, square, etc.). Different sets of these holes can have different shapes and sizes. That is, the shapes and sizes of these holes can differ from plenum to plenum and/or within a single plenum. Any combinations of all of the above geometrical variations and patterns of these holes described above may be used.

### Method of Processing Substrate Using Three Plenum Showerhead

FIGS. 7A-7C show a method 300 for performing an ALD process on the substrate 110 using the showerhead 200 in the substrate processing systems 250, 270, and 290. For example, the system controller 160 of the substrate processing systems 250, 270, and 290 performs the method 300. The system controller 160 controls the valves 130, 132, 134, and 136 to flow the gases through the first plenum 140 and the third plenum 202 as described below.

FIG. 7A shows a flowchart of the method 300. FIGS. 7B-7D illustrate various gas flows during the dose and purge steps described in the method 300. For clarity and simplicity of illustration, the showerhead 200 is identified in FIGS. 7B and 7C only by the reference numeral 200. All other reference numerals used in FIGS. 3A-6 to identify other features of the showerhead 200 are omitted in FIGS. 7B and 7C but are presumed to be present. Further, elements shown in FIGS. 3A-6 are referenced in the description of the method 300 below.

At 302, as shown in FIG. 7B, in a dose (DOSE) step, a precursor is supplied through a first plenum (e.g., the precursor plenum 140) of the showerhead 200 into the processing chamber 102 to deposit the precursor on the substrate 110 in the processing chamber 102. At 304, a purge gas (e.g., an inert gas) is trickled (i.e., supplied at a low flow rate called a first flow rate) through a third plenum (e.g., the third plenum 202) into the plasma source 106 to maintain a positive pressure in the plasma source 106.

At 306, as shown in FIG. 7C, in a post-dose purge (PDP) step (i.e., at the end of the dose step or after the supply of the precursor is stopped), the plasma source 106 and the processing chamber 102 are purged with the purge gas (e.g., an inert gas). In the post-dose purge step, the trickle of the purge gas supplied at 304 is maintained through the plasma source 106, and the purge gas is supplied through the first plenum (e.g., the precursor plenum 140) into the processing chamber 102. In some instances, the flow rate of the purge gas through the third plenum (e.g., the third plenum 202) into the plasma source 106 may be increased to more than the trickle (i.e., supplied at a second flow rate that is greater than the first flow rate).

At 308, as shown in FIG. 7D, in conversion (CONV) step, a process gas (e.g., nitrogen or hydrogen) is supplied through the third plenum (e.g., the third plenum 202) into the plasma source 106 at a flow rate greater than the trickle (i.e., at the second flow rate). (Nitrogen can also be supplied as the purge gas used in the purge steps of the method 300.)

At 310, the RF power supply 116 supplies RF power to the coil 114, which activates the process gas to strike plasma 115 in the plasma source 106. At 312, the method 300 waits for a predetermined period of time. During the predetermined period of time, the second plenum 144 (i.e., the radical holes 144) of the showerhead 200 filters the ions from the plasma 115 and supplies the radicals from the plasma 115 through the radical holes 144 into the processing chamber 102. The radicals react with the precursor that is deposited earlier on the substrate 110 during the dose step (at 302) to deposit the desired material (e.g., silicon nitride) on the substrate 110.

At 314, in a second, post-conversion purge (PCP) step, the RF power supply 116 stops the supply of the RF power to the coil 114, which extinguishes the plasma 115 in the plasma source 106. At 316, as shown in FIG. 7B, the plasma source 106 and the processing chamber 102 are purged as described in the post-dose purge step above. Specifically, in the second, post-conversion purge step, as in the post-dose purge step, the trickle of the purge gas is supplied through the third plenum (e.g., the third plenum 202) and is maintained through the plasma source 106, and the purge gas is supplied through the first plenum (e.g., the precursor plenum 140) into the processing chamber 102. In some instances, the flow rate of the purge gas through the third plenum (e.g., the third plenum 202) into the plasma source 106 may be increased to more than the trickle (i.e., supplied at the second flow rate that is greater than the first flow rate).

At 318, the method 300 determines whether to continue (i.e., repeat) the processing of the substrate 110 (e.g., whether a desired thickness of the material is deposited on the substrate 110). The method 300 repeats steps 302-318 until the desired thickness of the material is deposited on the substrate 110. The method 300 ends when the desired thickness of the material is deposited on the substrate 110.

In the method 300, during the purge steps, the third plenum 202 provides uniform gas flow in the plasma source 106 and in the processing chamber 102 (radially and azimuthally across the showerhead 200), which allows full evacuation of the precursor from the processing chamber 102 and prevents backstream flow of the precursor from the processing chamber 102 into the plasma source 106.

In some processes, depending on the recipe used for processing the substrate 110, the same or a different precursor may be used in the dose steps in alternate ALD cycles when steps 302-318 are repeated. For example, a first precursor may be used during a first dose step in a first ALD cycle of steps 302-318, and a second precursor may be used during a second dose step in a second ALD cycle of steps 302-318 that follows the first ALD cycle. These ALD cycles each comprising the steps 302-318 are repeated until the material of desired thickness is deposited on the substrate 110.

The above description of FIG. 3A onwards is provided using a deposition process as an example. The above description of FIG. 3A onwards, specifically of the use of the showerhead 200 and more specifically of the use of the third plenum 202, to provide uniform gas flow (radially and azimuthally across the showerhead 200) in the plasma source 106 and in the processing chamber 102 during the purge steps and preventing backstream flow of the precursor from the processing chamber 102 into the plasma source 106, applies equally if an etch process is performed on the substrate 110 in the substrate processing systems 250, 270, and 290 instead of the deposition process.

Further, the above description also applies equally to a cleaning process performed to clean the plasma source 106 and the processing chamber 102, where cleaning and purge gases and plasma are used to remove residual deposits from the plasma source 106 and the processing chamber 102. These residual deposits need to be fully evacuated from the plasma source 106 and the processing chamber 102 to prevent contamination of the plasma source 106 and the processing chamber 102. The uniform gas flow provided by the showerhead 200 (radially and azimuthally across the showerhead 200) described above can also prevent backstream flow of the contaminants from the processing chamber 102 into the plasma source 106 during the cleaning process.

### Additional Examples of Three-Plenum Showerhead

FIGS. 8A-12C show additional examples of three-plenum showerheads. These showerheads can be used in place of the showerhead 104 in the substrate processing system 100 shown in FIG. 1. As described below, a purge plenum provided in these showerheads prevents backflow of the precursor from the processing chamber 102 through the radical holes 144 into the plasma source 106 shown in FIG. 1. These showerheads comprise various arrangements of the purge plenum, the precursor plenum 140, the radical holes (also called a radical plenum, or a plasma plenum) 144, and the cooling channel 146, which are described below with reference to FIGS. 8A-12C. Throughout the following description, the reference numerals shown in FIGS. 8A-12C that are also shown and described above with reference to FIGS. 1-7D are not described again for brevity.

FIG. 8A shows an example of a three-plenum showerhead 400 according to the present disclosure. The showerhead 400 comprises the precursor plenum 140 and the radical plenum 144 with respective holes 142 and 144, and the cooling channel 146, which are already described above with reference to FIGS. 1-7D and are therefore not described again for brevity. The showerhead 400 additionally comprises a third plenum called a purge plenum 402. The purge plenum 402 is arranged between the precursor plenum 140 and the cooling channel 146. The radical plenum 144, the precursor plenum 140, the purge plenum 402, and the cooling channel 146 are disjoint (i.e., not in fluid communication with each other).

The purge plenum 402 comprises a plurality of holes 404-1, 404-2, . . . , and 404-N (collectively the holes 404, N being a positive integer). The holes 404 are arranged between the radical holes 144 and the precursor holes 142. That is, each hole 404 of the purge plenum is arranged between a radical hole 144 and a precursor hole 142. Thus, the holes of the radical plenum 144, the purge plenum 402, and the precursor plenum 140 are arranged in a sequence 144, 404, 142. The purge plenum 402 is used as a purge plenum to supply purge gas into the processing chamber 102 and also as an exhaust plenum to exhaust precursor from the processing chamber 102 into the exhaust system as described below in detail with reference to FIG. 8C. The operation of the showerhead 400 and the three plenums 144, 402, 142 is described with reference to FIG. 8C.

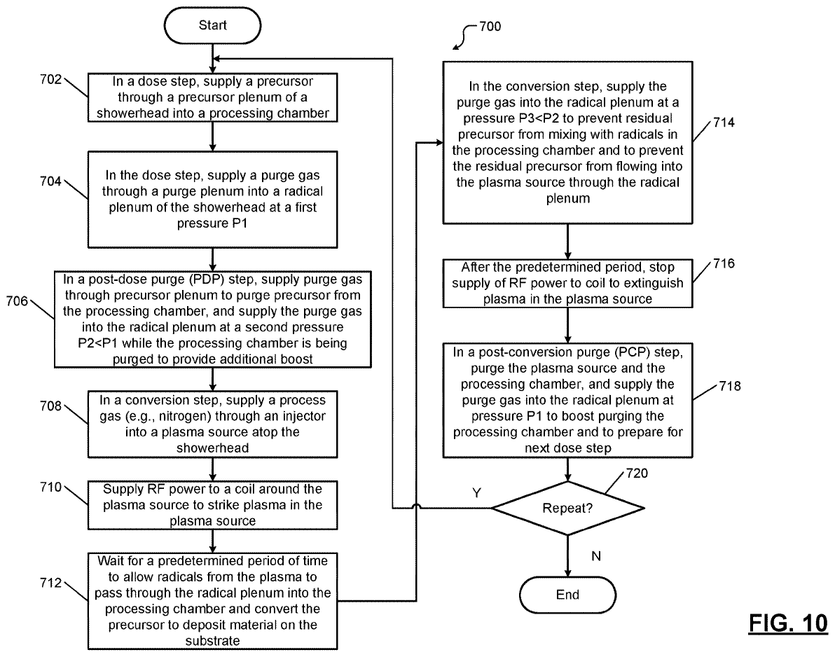

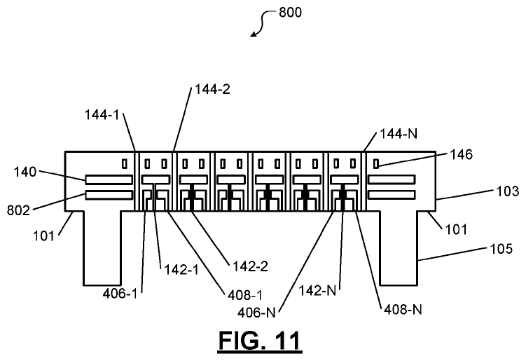

FIG. 8B shows a valve assembly 410 used to operate the purge plenums of the showerheads shown in FIGS. 8A-12C as described with reference to FIGS. 8C and 10. The valve assembly 410 is connected to the purge plenum of the showerheads shown in FIGS. 8A-12C. The valve assembly 410 is connected to the purge gas supply 124, the system controller 160, and the pump 164, all of which are shown and described above with reference to FIG. 1. The valve assembly 410 is used in conjunction with some of the valves of the gas delivery system 120 shown in FIG. 1. The system controller 160 controls some of the valves of the gas delivery system 120 to supply gases to the precursor plenum 140 and the injector 107 as described above with reference to FIG. 1. The system controller 160 controls the valve assembly 410 to operate the purge plenum of the showerheads shown in FIGS. 8A-12C as described with reference to FIGS. 8C and 10 to prevent backflow of the precursor from the processing chamber 102 through the radical holes 144 into the plasma source 106.

The valve assembly 410 comprises two valves that are mechanically and pneumatically part of the same valve assembly 410. The two valves are interlocked together such that when one valve opens, the other valve closes and vice-versa. Thus, the two valves are fast acting/switching valves. When one valve shuts off a gas from being delivered downstream to the processing chamber 102, the gas is not just blocked but is diverted through a secondary path called a divert path to the exhaust system, which prevents pressure build-up. The valve assembly 410 operates the two valves more like an on/off square wave than a sinusoidal wave passing between partial on and partial off, which prevents mixing of gases from occurring in the processing chamber 102.

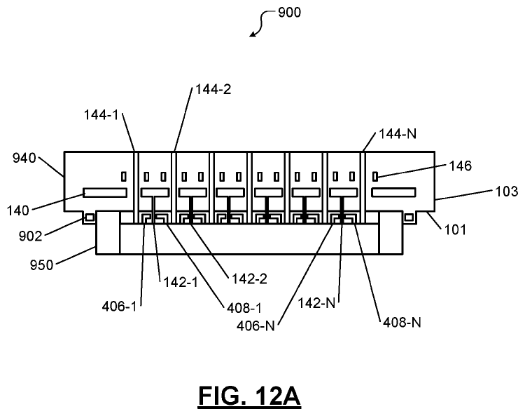

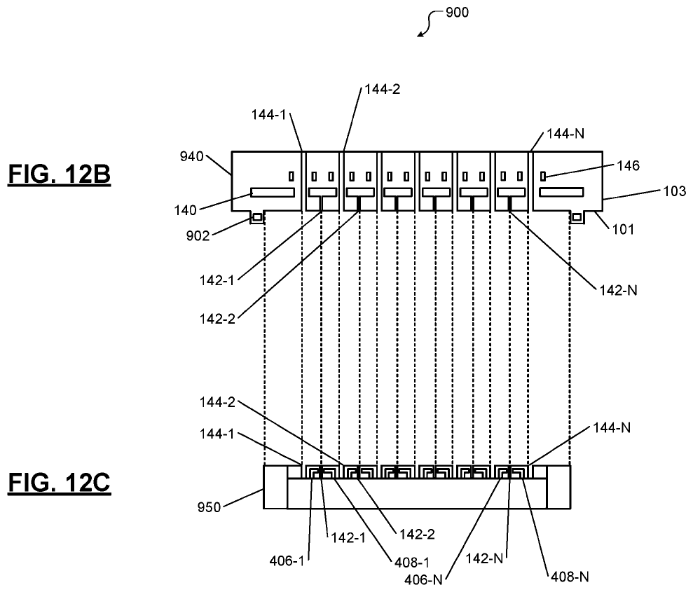

FIG. 8C shows flowchart of a method 500 for operating the purge plenum 402 of the showerhead 400 to prevent backflow of the precursor through the radical plenum 144 into the plasma source 106. The method 500 applies equally to the showerheads shown in FIGS. 11-12C. The purge plenum referenced in the description of FIG. 8C refers to the purge plenums 402, 802, and 902.

For example, FIG. 8C shows the method 500 for performing an ALD process on the substrate 110 using any of the showerheads 400, 800, and 900 in the substrate processing system 100. For example, the system controller 160 of the substrate processing system 100 can perform the method 500 using the elements shown in FIGS. 1, 8A, 8B, and 11-12C. The system controller 160 controls the valves of the gas delivery system 120 shown in FIG. 1 and the valve assembly 410 shown in FIG. 8B to flow the gases through the injector 107, the precursor plenum 140, and the purge plenum (e.g., 402, 802, or 902) of the showerheads 400, 800, and 900 as described below.

At 502, in a dose (DOSE) step, a precursor is supplied through the precursor plenum 140 of the showerhead into the processing chamber 102 to deposit the precursor on the substrate 110 in the processing chamber 102. At 504, in the dose step, a purge gas (e.g., an inert gas) is trickled (i.e., supplied at a low flow rate) through the purge plenum of the showerhead into the processing chamber 102. The purge gas flowing through the purge plenum prevents the precursor from backflowing (back-diffusing) through the radical holes 144 into the plasma source 106. Thus, most of the precursor flows to the substrate 110, and the flow of the purge gas through the purge plenum directs the precursor to the substrate 110.

At 506, in a post-dose purge (PDP) step (i.e., at the end of the dose step or after the supply of the precursor is stopped), the purge gas is supplied through the precursor plenum 140 into the processing chamber 102 to purge the precursor from the processing chamber 102. Additionally, in the post-dose purge step, the trickle of the purge gas is not supplied through the purge plenum. Instead, the purge plenum is used as an exhaust plenum by controlling the valve assembly 410 in a divert mode to boost removal of any residual precursor that may remain in the processing chamber 102 from the processing chamber 102 out into the exhaust system through the purge plenum. By not supplying the purge gas through the purge plenum, the purge plenum provides a low-pressure path for the residual precursor, which flows out through the purge plenum instead of flowing through the radical holes 144 into the plasma source 106. The residual precursor is purged out through the purge plenum into the exhaust system. Thus, the purge plenum prevents the residual precursor from flowing back into the plasma source 106 through the radical holes 144.

At 508, in a conversion (CONV) step, a process gas (e.g., nitrogen or hydrogen) is supplied through the injector 107 into the plasma source 106 atop the showerhead. Nitrogen can also be supplied as the purge gas used in the purge steps of the method 500. At 510, the RF power supply 116 supplies RF power to the coil 114, which activates the process gas to strike plasma 115 in the plasma source 106.

At 512, the method 500 waits for a predetermined period of time. During the predetermined period of time, the radical plenum 144 (i.e., the radical holes 144) of the showerhead filters the ions from the plasma 115 and supplies the radicals from the plasma 115 through the radical holes 144 into the processing chamber 102. The radicals react with the precursor that is deposited earlier on the substrate 110 during the dose step (at 302) to deposit the desired material (e.g., silicon nitride) on the substrate 110.

At 514, in the conversion step, the purge gas trickle is also supplied through the purge plenum into the processing chamber 102. The purge gas trickle supplied through the purge plenum creates a curtain of the purge gas around the radical holes 144 to prevent the radicals from mixing with any residual precursor remaining in the processing chamber 102, to prevent deposition of the residual precursor at the radical holes 144, and to prevent back streaming of the residual precursor through the radical holes 144 into the plasma source 106.

At 516, after the predetermined period, the RF power supply 116 stops the supply of the RF power to the coil 114, which extinguishes the plasma 115 in the plasma source 106. At 518, in a post-conversion purge (PCP) step, the plasma source 106 and the processing chamber 102 are purged by supplying the purge gas through the injector 107 into the plasma source 106 and by supplying the purge gas through the precursor plenum 140 into the processing chamber 102. Additional boost for purging the processing chamber 102 is provided by using the purge plenum as an exhaust plenum as described in the post-dose purge step above. Near the end of the post-conversion purge (PCP) step, the method 500 again begins supplying the purge gas trickle through the purge plenum to prepare for a next dose step.

At 520, the method 500 determines whether to continue (i.e., repeat) the processing of the substrate 110 (e.g., whether a desired thickness of the material is deposited on the substrate 110). The method 500 repeats steps 502-518 until the desired thickness of the material is deposited on the substrate 110. The method 500 ends when the desired thickness of the material is deposited on the substrate 110.

In some processes, depending on the recipe used for processing the substrate 110, the same or a different precursor may be used in the dose steps in alternate ALD cycles when steps 502-518 are repeated. For example, a first precursor may be used during a first dose step in a first ALD cycle of steps 502-518, and a second precursor may be used during a second dose step in a second ALD cycle of steps 502-518 that follows the first ALD cycle. These ALD cycles each comprising the steps 502-518 are repeated until the material of desired thickness is deposited on the substrate 110.

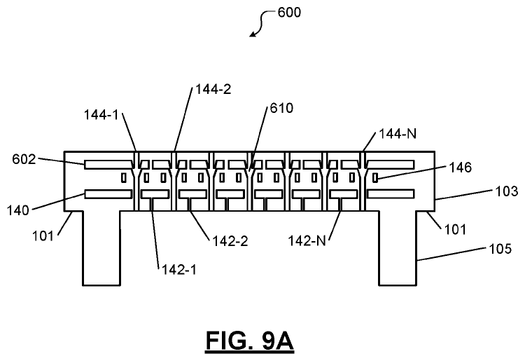

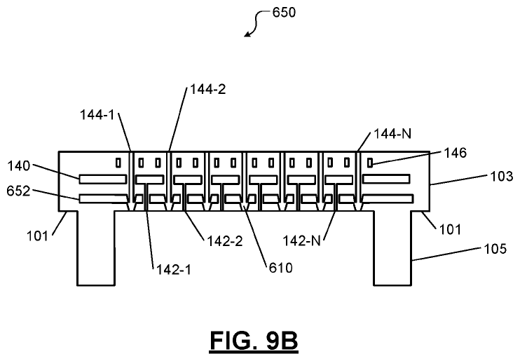

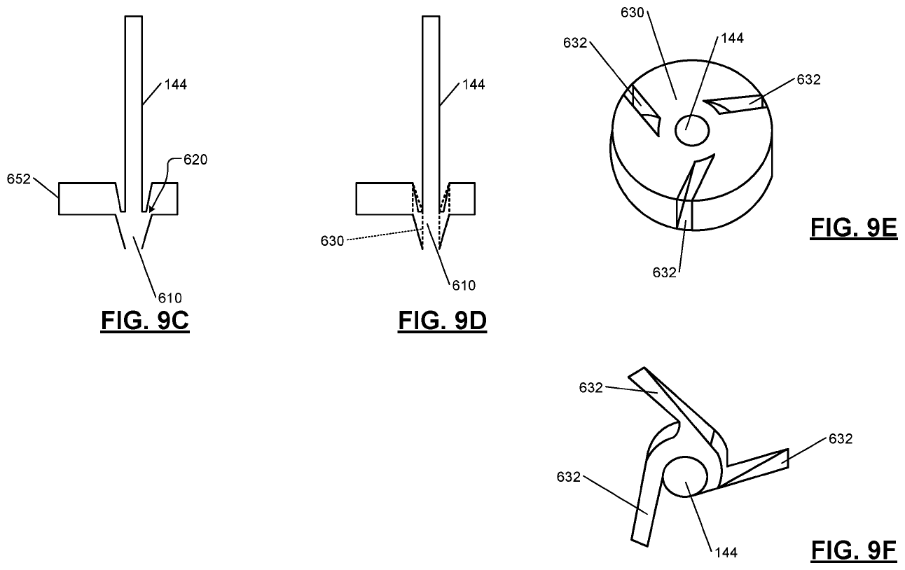

FIG. 9A shows an example of a three-plenum showerhead 600 according to the present disclosure. The showerhead 600 comprises the precursor plenum 140 and the radical plenum 144 with respective holes 142 and 144, and the cooling channel 146, which are already described above with reference to FIGS. 1-7D. The showerhead 600 additionally comprises a third plenum called a purge plenum 602. The purge plenum 602 is arranged above the cooling channel 146, which is arranged above the precursor plenum 140.

The purge plenum 602 is joined with (i.e., fluidly coupled to) the radical plenum 144. The purge plenum 602 intersects with the radical holes 144. The radical holes 144 are not cylindrical throughout the height (length) of the radical holes 144. Instead, at the intersections the purge plenum 602 and each of the radical holes 144, portions of the radical holes 144 and the purge plenum 602 are shaped to fluidly couple the purge plenum 602 and the radical holes 144 to each other. Generally, at the intersections, top and bottom portions of the purge plenum 602 extends downwards and radially inwards and fluidly connect to the radical holes 144. Specifically, at each of the intersections, a portion of the radical hole 144 flares upwards and radially outwards to form a funnel shaped structure 610. A top circumference of each of the funnel shaped structures 610 is attached to a hole at the bottom of the purge plenum 602. The hole at the bottom of the purge plenum 602 surrounds the radical hole 144. Additionally, at the intersections, a top portion of the purge plenum 602 that surrounds the radical holes 144 and that is above the funnel shaped structures 610, slopes downwards and radially inwards and is fluidly connected to the radical holes 144. Thus, when a purge gas is supplied to the purge plenum 602, the purge gas flows through the radical holes 144 downstream into the processing chamber 102 as described below in further detail with reference to FIG. 10. The holes of the radical plenum 144 and the precursor plenum 140 are arranged in an alternating sequence 144, 142.

FIG. 9B shows an example of a three-plenum showerhead 650 according to the present disclosure. The showerhead 650 comprises the precursor plenum 140 and the radical plenum 144 with respective holes 142 and 144, and the cooling channel 146, which are already described above with reference to FIGS. 1-7D. The showerhead 650 additionally comprises a third plenum called a purge plenum 652. The showerhead 650 differs from the showerhead 600 shown in FIG. 9A in that the purge plenum 652 is arranged below the precursor plenum 140, which is arranged below the cooling channel 146. Similar to the showerhead 600, the purge plenum 650 is joined with (i.e., fluidly coupled to) the radical plenum 144. The purge plenum 652 intersects with the radical holes 144. The radical holes 144 are not cylindrical throughout the height (length) of the radical holes 144. Instead, at the intersections the purge plenum 652 and each of the radical holes 144, portions of the radical holes 144 and the purge plenum 652 are shaped to fluidly couple the purge plenum 652 and the radical holes 144 to each other as described with reference to FIG. 9A. The showerhead 650 differs from the showerhead 600 in that in the showerhead 650, the funnel shaped structures 610 are formed near the bottom ends of the radical holes 144 instead of being formed near the upper ends of the radical holes 144. The purge plenum 652 of the showerhead 650 operates similar to the purge plenum 602 of the showerhead 600, as described below with reference to FIG. 10. The holes of the radical plenum 144 and the precursor plenum 140 are arranged in an alternating sequence 144, 142.

FIG. 9C-9F show an additional difference between the showerhead 650 and the showerhead 600. FIG. 9C shows an expanded view of the funnel shaped structure 610 of the showerhead 650. The showerhead 650 conducts heat radiated from the pedestal 108 (see FIG. 1), which is positioned proximate (adjacent) to the bottom of the showerhead 650 during ALD processes. The purge plenum 650 is located below the precursor plenum 140, which in turn is located below the cooling channel 146. Thus, the cooling channel 146 relatively distant (far) from the bottom of the showerhead 650. Further, in the showerhead 650, since the funnel shaped structures 610 are formed near the bottom ends of the radical holes 144, a thermal break (thermal discontinuity) 620 exists in the portion of the purge plenum 652 at the intersections between the purge plenum 652 and the radical holes 144. Accordingly, the heat absorbed by the bottom of the showerhead 650 is impeded by the thermal break 620 and has to travel the distance between the purge plenum 652 and the cooling channel 146.

In addition, in the showerhead 650, since the funnel shaped structures 610 are formed near the bottom ends of the radical holes 144, when a purge gas is supplied to the purge plenum 652, the purge gas flows unrestricted through the radical holes 144 downstream into the processing chamber 102. To facilitate heat conduction through the purge plenum 652 and to restrict the downstream flow of the purge gas through the radical holes 144, a cylindrical coupling member 630 shown in FIGS. 9D-9F is interposed at the intersections of between the purge plenum 652 and the radical holes 144.

FIG. 9D shows the coupling member 630 by dashed lines. FIG. 9E shows a perspective view of the coupling member 630 comprising gas passages 632 for flowing the purge gas from the purge plenum 652 into the radical holes 144. FIG. 9F shows a perspective view of the gas passages 632 and the radical hole 144. As shown in FIG. 9D and as seen in FIG. 9E, the coupling member 630 eliminates the thermal break 620 in the portion of the purge plenum 652 at the intersections between the purge plenum 652 and the radical holes 144. Accordingly, the coupling member 630 provides a path for the heat to flow from the bottom of the showerhead 650 to the cooling channel 146.

Additionally, as shown in FIG. 9E and as seen in FIG. 9F, the gas passages 632 extend between the top and bottom ends of the coupling member 630. The gas passages 632 slope from the top end to the bottom end of the coupling member 630. The gas passages 632 curve clockwise (or counter-clockwise) between the top and bottom ends of the coupling member 630. The gas passages 632 provide restrictive flow paths for the purge gas to flow from the purge plenum 650 into the radical holes 144. The gas passages 632 provide a vortex flow of the purge gas into the radical holes 144. The vortex flow of the purge gas through the radical holes 144 acts like an injection gas that drives the top to bottom flow through radical holes 144. The vortex flow controls the direction of gas flow through the radical holes 144 such that the purge gas flow facilitates only downward flow in the radical holes 144, which prevents back flow of the precursor through the radical holes 144 into the plasma chamber 106. While three flow paths 632 are shown, any number of flow paths can be used. Further, the flow paths 632 can be shaped and arranged differently than shown.

FIG. 10 shows flowchart of a method 700 for operating the purge plenums 602 and 652 of the showerheads 600 and 650 to prevent backflow of the precursor through the radical plenum 144 into the plasma source 106. The method 700 applies equally to the showerheads 600 and 650 shown in FIGS. 9A and 9B. The purge plenum referenced in the description of FIG. 10 refers to the purge plenums 602 and 652 of the showerheads 600 and 650 shown in FIGS. 9A and 9B.

For example, FIG. 10 shows the method 700 for performing an ALD process on the substrate 110 using any of the showerheads 600 and 650 in the substrate processing system 100. For example, the system controller 160 of the substrate processing system 100 can perform the method 700 using the elements shown in FIGS. 1, 8B, and 9A-9F. The system controller 160 controls the valves of the gas delivery system 120 shown in FIG. 1 and the valve assembly 410 shown in FIG. 8B to flow the gases through the injector 107, the precursor plenum 140, and the purge plenum (e.g., 602 or 652) of the showerhead 600 and 652 as described below.

At 702, in a dose (DOSE) step, a precursor is supplied through the precursor plenum 140 of the showerhead into the processing chamber 102 to deposit the precursor on the substrate 110 in the processing chamber 102. At 704, in the dose step, a purge gas (e.g., an inert gas) is supplied at a first pressure P1 through the purge plenum into the radical plenum 144 of the showerhead and into the processing chamber 102. The purge gas flowing through the purge plenum prevents the precursor from backflowing (back-diffusing) through the radical holes 144 into the plasma source 106. Thus, most of the precursor flows to the substrate 110, and the flow of the purge gas through the purge plenum directs the precursor to the substrate 110.

At 706, in a post-dose purge (PDP) step (i.e., at the end of the dose step or after the supply of the precursor is stopped), the purge gas is supplied through the precursor plenum 140 into the processing chamber 102 to purge the precursor from the processing chamber 102. Additionally, in the post-dose purge step, the purge gas is supplied through the purge plenum into the radical plenum 144 at a second pressure P2<P1 while the processing chamber 102 is being purged to boost removal of any residual precursor that may remain in the processing chamber 102 from the processing chamber 102 out into the exhaust system. The residual precursor is purged out of the processing chamber 102 into the exhaust system. Thus, by flowing the purge gas into the radical plenum 144 during the PDP step, the purge plenum prevents the residual precursor from flowing back into the plasma source 106 through the radical holes 144.

At 708, in a conversion (CONV) step, a process gas (e.g., nitrogen or hydrogen) is supplied through the injector 107 into the plasma source 106 atop the showerhead. Nitrogen can also be supplied as the purge gas used in the purge steps of the method 500. At 710, the RF power supply 116 supplies RF power to the coil 114, which activates the process gas to strike plasma 115 in the plasma source 106.

At 712, the method 500 waits for a predetermined period of time. During the predetermined period of time, the radical plenum 144 (i.e., the radical holes 144) of the showerhead filters the ions from the plasma 115 and supplies the radicals from the plasma 115 through the radical holes 144 into the processing chamber 102. The radicals react with the precursor that is deposited earlier on the substrate 110 during the dose step (at 302) to deposit the desired material (e.g., silicon nitride) on the substrate 110.

At 714, in the conversion step, the purge gas also supplied through the purge plenum into the radical plenum 144 at a third pressure P3<P2 and into the processing chamber 102. The purge gas supplied through the purge plenum into the radical plenum 144 prevents the radicals from mixing with any residual precursor remaining in the processing chamber 102, prevents deposition of the residual precursor at the radical holes 144, and prevents back streaming of the residual precursor through the radical holes 144 into the plasma source 106.

At 716, after the predetermined period, the RF power supply 116 stops the supply of the RF power to the coil 114, which extinguishes the plasma 115 in the plasma source 106. At 718, in a post-conversion purge (PCP) step, the plasma source 106 and the processing chamber 102 are purged by supplying the purge gas through the injector 107 into the plasma source 106 and by supplying the purge gas through the precursor plenum 140 into the processing chamber 102. Additional boost for purging the processing chamber 102 is provided by supplying the purge gas through the purge plenum into the radical plenum 144 at the first pressure P1. At the end of the post-conversion purge (PCP) step, the method 700 is ready for a next dose step.

At 720, the method 700 determines whether to continue (i.e., repeat) the processing of the substrate 110 (e.g., whether a desired thickness of the material is deposited on the substrate 110). The method 700 repeats steps 702-718 until the desired thickness of the material is deposited on the substrate 110. The method 700 ends when the desired thickness of the material is deposited on the substrate 110.

In some processes, depending on the recipe used for processing the substrate 110, the same or a different precursor may be used in the dose steps in alternate ALD cycles when steps 702-718 are repeated. For example, a first precursor may be used during a first dose step in a first ALD cycle of steps 702-718, and a second precursor may be used during a second dose step in a second ALD cycle of steps 702-718 that follows the first ALD cycle. These ALD cycles each comprising the steps 702-718 are repeated until the material of desired thickness is deposited on the substrate 110.

FIG. 11 shows an example of a three-plenum showerhead 800 according to the present disclosure. The showerhead 800 comprises the precursor plenum 140 and the radical plenum 144 with respective holes 142 and 144, and the cooling channel 146, which are already described above with reference to FIGS. 1-7D. The showerhead 800 additionally comprises a third plenum called a purge plenum 802. The showerhead 800 differs from the showerhead 400 shown in FIG. 8A in that the precursor plenum 140 is arranged below the cooling channel 146, and the purge plenum 802 is arranged below the precursor plenum 140. Additionally, the purge plenum 802 comprises two sets of holes 406-1, 408-1; 406-2, 408-2; . . . , and 406-N, 408-N (collectively the holes 406, 408). The holes 406, 408 are arranged between the radical holes 144, and each precursor hole 142 is arranged between the holes 406, 408. Thus, the holes of the radical plenum 144, the purge plenum 802, and the precursor plenum 140 are arranged in a sequence 144, 406, 142, 408. The purge gas plenum 802 provides a purge-gas curtain around the radical holes 144 to prevent deposition of the precursor at the radical holes 144 and prevents the backflow of the precursor through the radical holes 144 into the plasma source as described in detail with reference to FIG. 8C. The purge plenum 802 of the showerhead 800 operates similar to the purge plenum 402 of the showerhead 400, as described above with reference to FIG. 8C.

FIGS. 12A-12C show a three-plenum showerhead 900 according to the present disclosure. The showerhead 900 comprises the precursor plenum 140 and the radical plenum 144 with respective holes 142 and 144, and the cooling channel 146, which are already described above with reference to FIGS. 1-7D. The showerhead 900 additionally comprises a third plenum called a purge plenum 902. The showerhead 900 is similar to the showerhead 800 shown in FIG. 11 except that the purge plenum 902 of the showerhead 900 is arranged in a removable (detachable and re-attachable) plate 950 as shown in FIGS. 12B and 12C. The purge plenum 902 of the showerhead 900 is similar to the purge plenum 802 of the showerhead 800 in that the purge plenum 902 also comprises the holes 406, 408 that are arranged in the same sequence 144, 406, 142, 408.

Specifically, the showerhead 900 comprises an upper portion 940 and the plate 950 that forms a portion of the purge plenum 902. The upper portion 940 comprises the cooling channel 146, the precursor plenum 140, portions of the precursor holes 142, portions of the radical plenum (radical holes) 144, and a first portion of the purge plenum 902. The first portion of the purge plenum 902 in the upper portion 940 does not comprise the holes 406, 408 of the purge plenum 902. The plate 950 comprises portions of the precursor holes 142, portions of the radical plenum (radical holes) 144, a portion of the purge plenum 902 with the holes 406, 408. The following occurs when the plate 950 is attached to the upper portion 940 of the showerhead 900: The portions of the precursor holes 142 and the portions of the radical plenum (radical holes) 144 in the plate 950 mate with the respective portions of the precursor holes 142 and the respective portions of the radical plenum (radical holes) 144 in the upper portion 940. The portion of the purge plenum 902 with the holes 406, 408 in the plate 950 mates with the portion of the purge plenum 902 in in the upper portion 940. Thus, the holes of the radical plenum 144, the purge plenum 902, and the precursor plenum 140 are arranged in the sequence 144, 406, 142, 408.

The above description of FIG. 8A onwards is provided using a deposition process as an example. The above description of FIG. 8A onwards, specifically of the use of the showerheads 400, 600, 650, 800, and 900 and more specifically of the use of the purge plenums 402, 602, 652, and 902, to prevent backstream flow of the precursor from the processing chamber 102 into the plasma source 106, applies equally if an etch process is performed on the substrate 110 in the substrate processing system 100 instead of the deposition process.

Further, the above description also applies equally to a cleaning process performed to clean the plasma source 106 and the processing chamber 102, where cleaning and purge gases and plasma are used to remove residual deposits from the plasma source 106 and the processing chamber 102. These residual deposits need to be fully evacuated from the plasma source 106 and the processing chamber 102 to prevent contamination of the plasma source 106 and the processing chamber 102. The use of the showerheads 400, 600, 650, 800, and 900 and more specifically of the use of the purge plenums 402, 602, 652, and 902 described above can also prevent backstream flow of the contaminants from the processing chamber 102 into the plasma source 106 during the cleaning process.

In the showerheads 400, 600, 650, 800, and 900, the diameter of the holes of the third plenum (i.e., the purge plenum) is larger than the diameter of the precursor holes 142 and is smaller than the diameter of the radical holes 144. In these showerheads, the purge gas supplied through the purge plenum increases the separation between the precursor and plasma gases (radicals) to prevent back-diffusion of the precursor through the radical holes 144 into the plasma source 106. In these showerheads, the flow of the purge gas through the purge plenum as described above increases the pressure gradient from the substrate 110 to the bottom of the showerheads and the plasma/radical holes 144. The pressure gradient makes it increasingly difficult for the precursor to flow towards to the bottom of the showerheads and the plasma/radical holes 144. The purge gas flowing through the purge plenum prevents the precursor from backflowing (back-diffusing) through the radical holes 144 into the plasma source 106. Thus, most of the precursor flows to the substrate 110, and the flow of the purge gas through the purge plenum directs the precursor to the substrate 110.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber;
a plasma source to generate and supply plasma to the processing chamber; and
a showerhead disposed between the processing chamber and the plasma source to supply gases to the processing chamber and the plasma source and to supply the plasma to the processing chamber, the showerhead comprising:
a body having first, second, and side surfaces defining first and second plenums;
a first set of holes extending from the first plenum to the first surface, the first set of holes being in fluid communication with the processing chamber; and
a second set of holes extending from the second plenum to the second surface, the second set of holes being in fluid communication with the plasma source.

2. The substrate processing system of claim 1 wherein the second plenum and the second set of holes are inverted replicas of the first plenum and the first set of holes.

3. The substrate processing system of claim 1 wherein the showerhead supplies the gases through the first and second sets of holes uniformly radially and azimuthally across the showerhead.

4. The substrate processing system of claim 1 wherein the showerhead supplies the gases through the first and second sets of holes uniformly radially and azimuthally across the showerhead in opposite directions.

5. The substrate processing system of claim 1 wherein the showerhead supplies the gases through the first and second sets of holes to the processing chamber and the plasma source, respectively; and wherein the showerhead supplies the gases through the first and second sets of holes uniformly radially and azimuthally across the showerhead.

6. The substrate processing system of claim 1 wherein the showerhead is cylindrical, wherein the first and second plenums are stacked in an axial direction perpendicular to a diameter of the showerhead, and wherein the first and second plenums extend radially across the showerhead.

7. The substrate processing system of claim 1 wherein the processing chamber further comprises a pedestal and a substrate arranged on the pedestal, wherein the showerhead is cylindrical, wherein the first and second plenums are stacked in an axial direction perpendicular to a diameter of the showerhead, and wherein the first and second plenums extend radially fully across the substrate.

8. The substrate processing system of claim 1 wherein the second plenum and the second set of holes are disjoint from the first plenum and the first set of holes.

9. The substrate processing system of claim 1 wherein the showerhead is cylindrical, wherein the first and second plenums extend radially across the showerhead, and wherein the first and second sets of holes are distributed radially across the showerhead.

10. The substrate processing system of claim 1 wherein the showerhead is cylindrical and wherein the first and second sets of holes extend in an axial direction perpendicular to a diameter of the showerhead.

11. The substrate processing system of claim 1 wherein the first and second sets of holes have the same diameter.

12. The substrate processing system of claim 1 wherein showerhead further comprises a third set of holes that extend between the first and second surfaces and wherein the third set of holes are disjoint from the first and second plenums and the first and second sets of holes.

13. The substrate processing system of claim 12 wherein the showerhead is cylindrical, wherein the second set of holes supply one of the gases uniformly radially and azimuthally across the showerhead to the plasma source, and wherein the third set of holes supply the one of the gases uniformly radially and azimuthally across the showerhead from the plasma source to the processing chamber.

14. The substrate processing system of claim 12 wherein the showerhead is cylindrical and wherein the third set of holes extend in an axial direction perpendicular to a diameter of the showerhead.

15. The substrate processing system of claim 12 wherein the showerhead is cylindrical and wherein the third set of holes are distributed radially across the showerhead.

16. The substrate processing system of claim 12 wherein the showerhead is cylindrical and wherein the first, second, and third sets of holes are distributed interstitially radially across the showerhead.

17. The substrate processing system of claim 12 wherein the processing chamber further comprises a pedestal and a substrate arranged on the pedestal, wherein the showerhead is cylindrical, and wherein the third set of holes are distributed radially fully across the substrate.

18. The substrate processing system of claim 12 wherein the processing chamber further comprises a pedestal and a substrate arranged on the pedestal, wherein the showerhead is cylindrical, wherein the first and second plenums are stacked in an axial direction perpendicular to a diameter of the showerhead, wherein the first and second plenums extend radially fully across the substrate, and wherein the third set of holes are distributed radially fully across the substrate.

19. The substrate processing system of claim 12 wherein the showerhead is cylindrical, and wherein a diameter of the third set of holes is greater than or equal to diameters of at least one the first and second sets of holes.

20. The substrate processing system of claim 12 wherein the showerhead is cylindrical, and wherein the first and second sets of holes have a first diameter and wherein the third set of holes have a second diameter that is greater than the first diameter.

21. The substrate processing system of claim 12 wherein the third set of holes supply radicals from the plasma to the processing chamber.

22. The substrate processing system of claim 1 wherein the showerhead is cylindrical; wherein the showerhead further comprises a cooling channel disposed between the first and second plenums; and wherein the cooling channel and the first and plenums extend radially across the showerhead and are disjoint from each other.

23. The substrate processing system of claim 1 wherein the plasma source is dome shaped, elliptical, cylindrical, or conical.

24. The substrate processing system of claim 1 further comprising:
a gas delivery system to supply the gases to the showerhead; and
a controller configured to:
supply a first gas from the gases to the first plenum during a dose step of an atomic layer deposition (ALD) process;
supply a second gas from the gases to the second plenum to generate the plasma, the third set of holes supplying radicals from the plasma to the processing chamber; and
supply a third gas from the gases to the second plenum during a purge step of the ALD process,
wherein the third gas flows through the third set of holes uniformly radially and azimuthally across the showerhead into the processing chamber preventing flow of material from the processing chamber to the plasma source.

25. A showerhead for a substrate processing system comprising:
a body having first, second, and side surfaces defining first and second plenums, the first and second surfaces being opposite to each other;
a first set of holes extending from the first plenum to the first surface; and
a second set of holes extending from the second plenum to the second surface.

26. The showerhead of claim 25 wherein the second plenum and the second set of holes are inverted replicas of the first plenum and the first set of holes.

27. The showerhead of claim 25 wherein the showerhead is cylindrical, wherein the first and second plenums are stacked in an axial direction perpendicular to a diameter of the showerhead, and wherein the first and second plenums extend radially across the showerhead.

28. The showerhead of claim 25 wherein the second plenum and the second set of holes are disjoint from the first plenum and the first set of holes.

29. The showerhead of claim 25 wherein the showerhead is cylindrical, wherein the first and second plenums extend radially across the showerhead, and wherein the first and second sets of holes are distributed radially across the showerhead.

30. The showerhead of claim 25 wherein the showerhead is cylindrical and wherein the first and second sets of holes extend in an axial direction perpendicular to a diameter of the showerhead.

31. The showerhead of claim 25 wherein the first and second sets of holes have the same diameter.

32. The showerhead of claim 25 further comprising a third set of holes that extend between the first and second surfaces wherein the third set of holes are disjoint from the first and second plenums and the first and second sets of holes.

33. The showerhead of claim 32 wherein the showerhead is cylindrical and wherein the third set of holes extend in an axial direction perpendicular to a diameter of the showerhead.

34. The showerhead of claim 32 wherein the showerhead is cylindrical and wherein the third set of holes are distributed radially across the showerhead.

35. The showerhead of claim 32 wherein the showerhead is cylindrical and wherein the first, second, and third sets of holes are distributed interstitially radially across the showerhead.

36. The showerhead of claim 32 wherein the showerhead is cylindrical, and wherein the third set of holes are greater in diameter than the first and second sets of holes.

37. The showerhead of claim 32 wherein the showerhead is cylindrical, and wherein the first and second sets of holes have a first diameter and wherein the third set of holes have a second diameter that is greater than the first diameter.

38. The showerhead of claim 25 wherein the showerhead is cylindrical, wherein the showerhead further comprises a cooling channel disposed between the first and second plenums, and wherein the cooling channel and the first and plenums extend radially across the showerhead and are disjoint from each other.
